(19) United States
(12) Patent Application Publication
(10) Pub. No.: US 2008/0272439 A1
(43) Pub. Date: Nov. 6, 2008

(54) SMALL GEOMETRY MOS TRANSISTOR WITH THIN POLYCRYSTALLINE SURFACE CONTACTS AND METHOD FOR MAKING

(75) Inventors: Ashok K. Kapoor, Palo Alto, CA (US); Madhukar B. Vora, Los Gatos, CA (US)

Correspondence Address: PERKINS COIE LLP, P.O. BOX 1208, SEATTLE, WA, 98111-1208, US

(73) Assignee: DSM SOLUTIONS, INC., Los Gatos, CA (US)

(21) Appl. No.: 12/113,106

(22) Filed: Apr. 30, 2008

Related U.S. Application Data
(60) Provisional application No. 60/927,175, filed on May 1, 2007.

(51) Int. Cl. H01L 29/78; H01L 21/8238

(52) U.S. Cl. 257/369; 438/221; 257/E29.255; 257/E21.421

(57) ABSTRACT

Process for fabrication of MOS semiconductor structures and transistors such as CMOS structures and transistors with thin gate oxide, polysilicon surface contacts having thickness on the order of 500 Angstroms or less and with photo-lithographically determined distances between the gate surface contact and the source and drain contacts. Semiconductor devices having polysilicon surface contacts wherein the ratio of the vertical height to the horizontal dimension is approximately unity. Small geometry Metal-Oxide-Semiconductor (MOS) transistor with thin polycrystalline surface contacts and method and process for making the MOS transistor. MOS and CMOS transistors and process for making. Process for making transistors using Silicon Nitride layer to achieve strained Silicon substrate. Strained Silicon devices and transistors wherein fabrication starts with strained Silicon substrate. Strained Silicon devices which use a Silicon Nitride film applied to the substrate at high temperature and which use differential thermal contraction rates during cooling to achieve strained Silicon.

### CROSS-REFERENCE TO RELATED APPLICATIONS

This application claims the benefit of priority under one or more of 35 U.S.C. 119 and 35 U.S.C. 120 and is related to U.S. Provisional Patent Application No. 60/927,175 filed May 1, 2007 naming as inventors Ashok K. Kapoor and Madhukar B. Vora and entitled SMALL GEOMETRY CMOS TRANSISTOR WITH THIN POLYCRYSTALLINE SURFACE CONTACTS, which application is hereby incorporated by reference.

### FIELD OF INVENTION

This invention pertains generally to various transistor structures including Metal-Oxide-Semiconductor (MOS) transistors and the associated method or process for making these transistor structures, and more particularly to Complementary-Metal-Oxide-Semiconductor (CMOS) transistors (as well as NMOS and PMOS devices) and the associated method or process for making them and including small geometry CMOS transistors having thin polycrystalline Silicon surface contacts, and small geometry CMOS transistors using strained silicon for higher carrier mobility, higher drain current and higher switching speed.

### BACKGROUND

Conventional CMOS processing has encountered difficulties as device sizes have been scaled down to achieve greater packing density and faster speed. As of about 2005, CMOS processing technology used sub-100 Nanometer line widths (minimum feature size), but scaling devices downward to line widths substantially smaller than 100 Nanometers, say to the 45 nanometers line widths and features sizes prevalent at the time of the filing of this application in 2008, has proven to be a challenge. Achieving even smaller line widths and feature sizes according to next generation design rules, such as for example 32 nanometer design rules and smaller will be even a greater challenge.

One of the problems encountered in conventional CMOS design is the inability to scale devices down in the vertical dimension as much as they can be scaled down in the horizontal dimension. For example, the thickness of the Polycrystalline Silicon gate electrode has decreased in the vertical dimension only about 50% while the lateral or horizontal dimensions of the gate electrode has decreased by over 90%. This causes horizontal dimension scaling problems in self-aligned gate CMOS. Self-aligned gate CMOS uses a spacer dielectric around the vertical sidewalls of the gate electrode to insulate the gate electrode from the adjacent source and drain electrodes. The horizontal thickness of the spacer determines the minimum overall horizontal dimension of the transistor. Conventionally, the horizontal thickness of the spacer is determined by the thickness of the Polycrystalline Silicon layer from which the gate electrode is formed so it does not scale proportionately with the other horizontal dimensions of the device because the vertical thickness of the Polycrystalline Silicon layer does not scale in proportion to the horizontal scaling.

Two processing steps in particular are becoming increasingly difficult as dimensions are scaled down further and further are: (1) formation of shallow source and drain regions (important to hold down short channel leakage currents), (2) silicidation of shallow source and drain regions without causing junction leakage, and (3) etching and filling of contact holes to the source and drain regions.

In one class of CMOS structures, the source, drain, and gate contacts on the surface of the substrate are formed by depositing a layer of Polycrystalline Silicon that is the thickness of the vertical dimension of the desired source, drain, and gate contacts. Then, the Polycrystalline Silicon layer is etched to define separate source, drain and gate contacts.

Problematically, when the Polycrystalline Silicon layer in conventional devices is thinner than about 1000 Angstroms (100 nm), the etching of the Polycrystalline Silicon layer becomes erratic in that the amount of over-etch into the underlying Silicon substrate becomes unpredictable. In some active areas the amount of over-etch may be 200 Angstroms (20 nm) or more and in other active areas on the same wafer, the over-etch may be less than and frequently substantially less than 200 Angstroms, or conversely greater than and frequently substantially greater than 200 Angstroms. This makes maintaining a particular feature size or transistor structure difficult to reliably achieve and maintain across a large wafer.

Another problem in the conventional CMOS fabrication processes when etching thin Polycrystalline Silicon layers to form surface contacts is the lack of straight vertical edges. Sometimes the etch leaves convex sides that bulge out, and sometimes the etch leaves concave sides which curve inward. If small 45 nm wide surface contacts are being attempted, these concave sides are undesirable as they weaken the structure and can destroy it altogether. Convex sides are also a problem because if spacers are being used on concave sides to make a self-aligned gate, the concave sides add to the width of the spacer (which is fixed by the properties of the anisotropic etch). This means the gate surface contact may be thinner than desired in the horizontal dimension or may be squeezed so much by the abnormally narrow space between the spacers as to prevent the Polycrystalline Silicon from reaching the surface of the gate oxide or adversely affecting the electrical conductivity of the gate contact.

### SUMMARY

In one aspect, embodiments provide a small geometry MOS transistor with thin polycrystalline surface contacts and method and process for making the MOS transistor.

In another aspect, embodiments provide a process to make Metal-Oxide-Semiconductor (MOS) transistor such as a Complementary Metal-Oxide-Semiconductor (CMOS) comprising: forming a Shallow Trench Isolation (STI) region in a P doped strained or unstrained Silicon semiconductor substrate to define a first active area for a P-channel MOS transistor (PMOS transistor) and a different second active area for a N-channel MOS transistor (NMOS transistor); implanting an N-type well in the active area of the PMOS transistor and implanting a P-type well in the active area of the NMOS transistor; forming a layer of Silicon Dioxide gate insulator over the semiconductor substrate; masking and etching to remove the gate oxide from at least areas in the active areas of the PMOS and NMOS transistors where source and drain surface contacts are to be formed and, if back gate contacts are to be used, from the area where the back gate contacts are to be formed; depositing a layer of Polycrystalline Silicon (polysilicon) over the wafer; and masking and etching the layer of Polycrystalline Silicon to: (i) define at least a source, gate and drain polysilicon surface contact and a back gate polysilicon surface contact within the active area of the PMOS device with the gate surface contact located over the gate oxide, and (ii) define at least a source, gate and drain polysilicon surface contact and a back gate polysilicon surface contact within the active area of the NMOS device with the gate surface contact located over the gate oxide.

In still another aspect, embodiments provide a process for making complementary Metal-Oxide-Semiconductor (CMOS) devices using a Silicon Nitride layer to achieve a strained Silicon substrate, comprising: depositing a layer of Polycrystalline Silicon (polysilicon) over at least areas of a Silicon semiconductor substrate where the CMOS device is to be formed; depositing a first layer of Silicon Nitride on top of the Polycrystalline Silicon (polysilicon); masking and etching the layer of polysilicon to define at least source, gate, and drain surface contacts, and a back gate surface contact if used within the active area with the gate surface contact located over the gate oxide and the masking and etching creating gaps between the surface contacts; depositing an effective thickness of a second layer of Silicon Nitride over the entire wafer so as to be in contact with the Silicon substrate between at least the gate and the source and drain surface contacts under process conditions which will cause differential thermal expansion rates between the Silicon semiconductor substrate and the second layer of Silicon Nitride to place the Silicon semiconductor substrate under strain; depositing a layer of Silicon Dioxide to a thickness at least sufficient to fill the gaps between the surface contacts not filled by the second Silicon Nitride layer; and planarizing the layer of Silicon Dioxide so as to leave its top surface substantially flush with the top of the deposited second layer of Silicon Nitride.

In yet another aspect, embodiments provide a Metal-Oxide-Semiconductor (MOS) transistor comprising: an active area defined within a semiconductor substrate for the MOS transistor; a gate surface contact positioned over the active area and formed over a gate insulator layer and comprising Polycrystalline Silicon (polysilicon) doped with conductivity enhancing impurities; source and drain surface contacts comprising Polycrystalline Silicon (polysilicon) doped to a first conductivity type, the source surface contact formed so that it is positioned away from a first side of the gate surface contact and spaced by a first photo-lithographically defined distance away from the gate surface contact; and the drain surface contact formed such that it is positioned away from a second side of the gate surface contact and spaced by a second photo-lithographically defined distance away from the gate surface contact; self-aligned source and drain regions doped to the first conductivity type and formed in the semiconductor substrate so as to be in electrical contact with the source and drain surface contacts, respectively; and an insulator formed between the source and gate surface contacts and between the drain and gate surface contacts.

In even other aspects, embodiments provide various semiconductor and transistor devices and structures made or formed according to the methods and processes described.

Other aspects will be apparent from the detailed description and accompanying drawings.

### BRIEF DESCRIPTION OF THE DRAWINGS

FIGS. 1-5 show cross-sectional views of exemplary non-triple-well (no deep N-well) and triple-well (including deep N-well which encloses the N-well of the PMOS device and the P-well of the NMOS device) isolated CMOS transistor structure built according to a first manufacturing process 100 (sometimes referred to as a poly-first process) for making or forming a small MOS transistor with thin polycrystalline silicon surface contacts at various stages in the process, wherein:

FIGS. 1A and 1B show non-triple-well and triple-well isolation embodiments respectively of a cross-section through the active area of the exemplary CMOS transistor structure built according to a first process at a stage of the process after formation of the STI trenches and growth of the gate insulator as well as after an optional step of etching the gate insulator layer off the areas where the source and drain metal contacts will be located;

FIGS. 2A and 2B show cross-sections of the same exemplary CMOS transistor structure FIG. 1A and FIG. 1B respectively, built according to a first process at a stage of the process after deposition of a thin layer of Polycrystalline Silicon and a layer of Silicon Nitride have been deposited on top of the Polycrystalline Silicon layer, and for FIG. 2B after masking the polysilicon layer to define the areas of Silicon Nitride and Polycrystalline Silicon to be removed during later plasma etches;

FIGS. 3A and 3B show cross-sections of the exemplary CMOS transistor structure in FIG. 1 built according to a first process at a stage of the process after deposition of the thin polysilicon after etching the polysilicon (embodiments provide for the polysilicon to be doped and then etched or etched and then doped) to define all the surface contacts, and after filling the gaps between surface contacts with Silicon Dioxide and polishing it back flush with the tops of the Silicon Nitride caps and during the masking and link implant;

FIGS. 4A and 4B show cross-sections of the exemplary CMOS transistor structure in FIG. 1 built according to a first process at a stage of the process after link implants to form link regions, after removal of the Silicon Nitride layers and during an N-type implant to dope the surface contacts of the NMOS device and the back gate contact of the PMOS device N-type; and

FIGS. 5A and 5B show cross-sections of the exemplary CMOS transistor structure in FIG. 1 built according to a first process at a stage of the process showing the thin polysilicon and thin gate oxide, the photo-lithographically determined distances between the gate and source and drain contacts, the shallow source, drain and link regions and the silicide on top of the polysilicon instead of on top of the substrate at the source and drain regions.

FIGS. 6-10 show cross-sectional views of exemplary non-triple-well (no deep N-well) and triple-well (including deep N-well which encloses the N-well of the PMOS device and the P-well of the NMOS device) isolated CMOS transistor structure built according to a second process for 200 at various stages in the process, wherein:

FIGS. 6A and 6B show cross-sections of the exemplary CMOS transistor structure built according to the second processes at a stage of the process after formation of the STI trenches and growth of the gate insulator and an optional step of etching the gate insulator layer off the areas where the source and drain metal contacts will be located;

FIGS. 7A and 7B show cross-sections of the exemplary CMOS transistor structure built according to the second processes at a stage of the process after deposition of a thin layer of Polycrystalline Silicon (polysilicon) and a layer of Silicon Nitride (nitride) have been deposited and after masking the polysilicon layer to define the areas of Polycrystalline Silicon to be doped N-type and during the N-type impurity implant.

FIGS. 8A and 8B show cross-sections of the exemplary CMOS transistor structure built according to the second processes at a stage of the process after masking the polysilicon layer for the P-type implant and during the P-type implantation.

FIGS. 9A and 9B show cross-sections of the exemplary CMOS transistor structure built according to the second processes at a stage of the process after masking for the PMOS device link implants and during the PMOS device link implants to form link regions, where oink regions for the NMOS device have been previously formed.

FIGS. 10A and 10B show cross-sections of the exemplary CMOS transistor structure built according to the second processes at a stage of the process showing the thin polysilicon surface contacts with silicide caps with contact openings to the silicide and metal interconnects to the silicide, as well as showing the thin gate oxide, and the photolithographically determined distances between gate and source and drain contacts, as well as the shallow source, drain and link regions that improve the short channel leakage current and which are made possible the silicide being on top of the polysilicon surface contacts and not at the surface of the substrate.

FIGS. 10A and 10B also show the thin gate oxide, and show the photolithographically determined distances between the gate and source and drain contacts, as well as the shallow source, drain and link regions that improve the short channel leakage current and which are made possible by the fact the silicide is on top of the polysilicon surface contacts and not at the surface of the substrate.

FIGS. 11A and 11B show a cross-sectional view of exemplary a non-triple-well (no deep N-well) and triple-well (including deep N-well which encloses the N-well of the PMOS device and the P-well of the NMOS device) isolated CMOS transistor structure built according to a third process for 300 at an intermediate stage of construction of a strained Silicon embodiment constructed using a Silicon Nitride film applied at a high temperature so as to be in direct contact with the silicon of the substrate.

FIGS. 12-16 show cross-sectional views of exemplary triple-well (including deep N-well which encloses the N-well of the PMOS device and the P-well of the NMOS device) and non-triple-well (no deep N-well) isolated CMOS transistor structure built according to a fourth process for 400 at various stages in the process, wherein:

FIGS. 12A and 12B show cross-sections of the exemplary CMOS transistor structure built according to the fourth process 400 and constructed using an oxide-first construction technique to avoid over-etch and provide better control of etching of thin Polycrystalline Silicon layers;

FIGS. 13A and 13B show cross-sections of the exemplary CMOS transistor structure built according to the fourth process at a stage in the process after formation of the photoresist mask to define the sizes and locations of the source and drain contacts.

FIGS. 14A and 14B show cross-sections of the exemplary CMOS transistor structure built according to the fourth process at a stage in the process after etching the surface contact openings and removing all the photoresist.

FIGS. 15A and 15B show cross-sections of the exemplary CMOS transistor structure built according to the fourth process at a stage in the process after deposition of Polycrystalline Silicon and polishing it back to flush with the top of nitride film, and also shows the masking and implantation for the link implants for the PMOS device.

FIGS. 16A and 16B show cross-sections of the exemplary CMOS transistor structure built according to the fourth process at a stage in the process during implantation of N-type impurities into the polysilicon surface contact layer after previous implantation of P-type impurities into the polysilicon surface contact layer.

### DETAILED DESCRIPTION OF EXEMPLARY EMBODIMENTS

In order to scale Complementary Metal-Oxide-Semiconductor (CMOS) devices down to 45 nanometer (45×10−9 meter) or less horizontal feature sizes (for example according to 45 nm design rules), it is necessary to scale the vertical dimensions of the polysilicon gate so as to maintain an aspect ratio close to one. Accordingly, it is desirable to be able to reliably make surface contacts that are 500 Angstroms (500×10−10 meter) or 50 nm (50×10−9 meter) or less thick so that the ratio of 45/50=0.9 (or 50/45=1.11) which is within the range of unity ratio. Of course it will be understood that the ratio can be adjusted to unity or to a value closer to unity by modifying the thickness or the surface contacts (for example to be 450 Angstrom rather than 500 Angstrom) if desired, or to modify the feature size.

Using the methods and processes described herein, very small CMOS transistors (as well as very small NMOS and PMOS devices) with thin Polycrystalline Silicon surface contacts may be formed or fabricated. These thin Polycrystalline Silicon surface contacts may have a small vertical height or thickness and be on the order of 450-500 Angstroms (45-50 nm) thick or less with 45 nm or smaller horizontal dimensions in a 45 nm or less design rules process. The methods and processes described here are also applicable to smaller structures and other current and future design rules including next generation design rules aimed at 32 nm and smaller structures wherein the thin Polycrystalline Silicon surface contacts may be formed to have vertical height or thickness on the order of 300 Angstrom (30 nm). As described elsewhere herein, it is advantageous that the ratio of vertical height to horizontal dimension be about unity or about 1.0, though exact unity in not required. Variations from unity on the over of ±20% from unity are usable, more desirably ±10% variation or less, and ±5% from unity is more advantageous. These tolerances are non-limiting examples and represent improvements over conventional structures and methods where the thickness of the Polycrystalline Silicon surface contacts may be a factor of 2× (e.g., 1000 Angstrom or 100 nm) or 3× (e.g., 1500 Angstrom or 150 nm) even for 45 nm design rule line width or feature size structures.

In accordance with one non-limiting embodiment, spacing between the gate surface contact and the source and drain contacts is determined photo-lithographically by a single mask. That same single mask is used to define the size and spacing all of the gate, source, and drain surface contacts (and of an optional back gate surface contact, if such back gate surface contact is used) so all of these surface contacts could be considered to be self-aligned since only one mask is used to define them all and there is no alignment issue. It is also possible to limit over-etch into the underlying single crystal substrate to only about 50 Angstroms (5 nm).

The inventive process and structures created by it have many advantages, including but not limited to some combination of or all of the following six advantages which may be realized separately and in any combination.

First, CMOS transistors with very small line widths such as 45 nanometers can be created with appropriately scaled vertical dimensions such as gate oxide which is only about 10-12 Angstroms thick and Polycrystalline Silicon surface contacts which is only about 500 Angstroms thick with good etching properties and over-etch into the substrate of only about 50 to 100 Angstroms. This better aspect ratio means there are fewer photolithographic and other processing problems related to very tall, very thin structures and very tall, very thin contact openings.

Second, very shallow source and drain regions and very shallow link regions can be formed in the substrate without fear of the silicide which is formed on the surface of the substrate at the source and drain locations in the conventional process penetrating the source and drain regions and shorting them out. This is because the silicide is formed in the new process on top of the Polycrystalline Silicon surface contacts and in at least one embodiment is about 500 Angstroms away from the surface of the substrate. The depth of the source and drain regions and the link implant regions are a major factor in the short channel leakage current characteristics. The extremely shallow source, drain, and link regions which can be created in the new process mean the short channel leakage current of the new transistor structure is less. This substantially improves static power consumption (power consumption by leakage current when the CMOS is not switching and no current should be flowing).

Third, the area of each finished transistor on the die at 45 nanometer design rules is less than a conventional CMOS transistor at 45 nanometer design rules. This is because the spacing between the gate surface electrode and the source and drain surface electrodes is controlled photo-lithographically and can be 45 Nanometers. This is compared to the minimum spacing between the gate electrode and the source and drain electrodes being conventional determined by the width of the anisotropically etched spacer formed from a layer of Silicon Nitride and Silicon Dioxide which is 1000 to 1500 Angstroms thick, this spacer width typically being 60 Nanometers or more.

Fourth, better strained Silicon structures can be achieved using the new process. One way of achieving strained Silicon is to deposit a Silicon Nitride layer on the surface of the active area under appropriate process conditions to create strained silicon nitride layer. In conventional processes, the spacer around the gate electrode is formed first and then the layer of Silicon Nitride responsible for straining the silicon is deposited and the structure is cooled. This leaves the Silicon Nitride (nitride) spaced away from the walls of the gate surface contact by about 60 Nanometers. More strain would result if the nitride were placed right next to the vertical wall of the gate surface contact. In the new structure, because the Silicon Nitride layer that is used to strain the Silicon of the substrate is much closer to the vertical walls of the gate surface electrode than is the case in the prior art, more strain on the channel region results. Putting permanent strain on the single crystal Silicon of the substrate increases its mobility and increases the output current and consequent increases the drive capability of the transistor. This increases its switching speed. The closer the Silicon Nitride layer deposited on the surface of the active area substrate is to the vertical wall of the gate surface electrode, the greater the strain which is put on the channel and the MOS transistor and the greater is the performance increase.

Fifth, at least because the gate, source, and drain surface contacts (and back gate contact if used) are all made of doped Polycrystalline Silicon and the field regions outside each active area is STI Silicon Dioxide at the surface of the substrate, poly level interconnects may be fabricated to connect the terminals of each transistor to other device terminals, buses or power “rails”. This gives another level of interconnects and can reduce the number of metal layers needed for the various interconnections of a given circuit and can reduce the number of masks needed to define contact openings and vias.

Other advantages of the inventive processes, methods, structures, devices, and transistors will be apparent from the other description provided herein.

Headers and subheaders if present in this description are provided for the convenience of the reader should not be interpreted to limit the scope of the invention in any way. Various aspects and features of different embodiments of the invention are described throughout the specification and are not limited to particular sections.

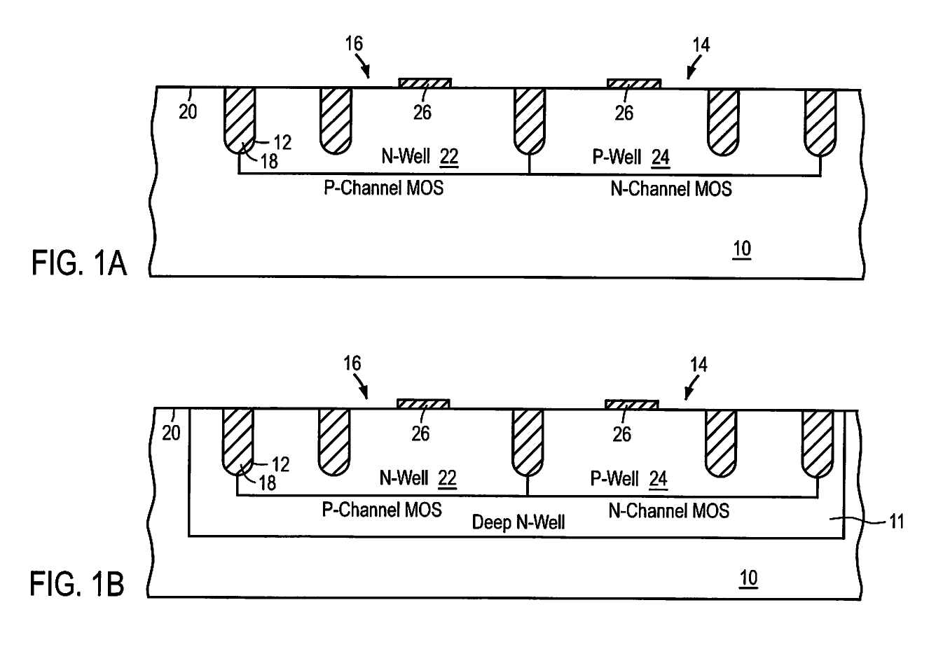

Exemplary embodiments of structures and processes for making them that may be formed using one or more of the inventive processes are illustrated by way of example but not limitation in FIGS. 1-16. These are briefly highlighted so that an overall understanding of the different structures and alternative embodiments of the structures, devices, methods, and processes may be more readily understood when described in detail hereafter.

### Exemplary Embodiment of Device and Poly-First Manufacturing Process for Small MOS Transistor With Thin Polycrystalline Silicon Not Doped Before Etching to form Surface Contacts

Attention is now directed to an exemplary embodiment of a new fabrication process referred to as “Poly First” Process 100 for manufacturing a Small MOS transistor with thin Polycrystalline Silicon surface contacts. In this exemplary process the polycrystalline silicon is not doped before it is etched. This process permits making very small MOS transistors with Polycrystalline Silicon surface contacts which can be on the order of 500 angstrom thick and using 40 nanometer design rules (minimum feature size in horizontal dimension 40 Nanometers). As a further example of how much smaller the MOS transistors may be using the inventive structure and method as compared to conventional MOS transistors, for a gate horizontal dimension of about 65 nm the conventional spacers on either side of the gate would be about 60 nm each for a total horizontal width of 185 nm. The inventive structure and method eliminate these spacers so that the inventive gate consumes only 65 nm of horizontal width dimension, reducing the size to about ⅓ of the conventional gate dimension.

Because the Polycrystalline Silicon layer from which the surface contacts are to be made in the new CMOS process is also much thinner (advantageously 500 Angstroms or less) than in the conventional CMOS process (typically 1500 to 1000 Angstroms), there is much less over-etch into the Silicon substrate in the new CMOS process than in the conventional CMOS process because over-etch is a percentage of the thickness of the layer. Further, because in the new CMOS process, etching of the Polycrystalline Silicon layer is line, gap, line, gap, line for the source, gate, and drain surface electrodes, control over the gap distance between surface electrodes is controlled photo-lithographically. Therefore, in the new process, the horizontal space between the gate and each of the source and drain surface contacts can be the minimum distance permitted by the design rules. No such control exists in the conventional CMOS process, where the horizontal space between the gate electrode and the source and drain contacts is controlled by the horizontal thickness of a spacer dielectric structure used to isolate the gate surface contact from the source and drain electrodes. The horizontal thickness of the spacer dielectric structure is a function of the thickness of the Polycrystalline Silicon layer (1500-1000 Angstroms) and the Silicon Dioxide layer deposited over it from which the spacer dielectric structure is formed by an anisotropic etch process. The thicker is the layer of Silicon Dioxide (and it must be at least as thick as the Polycrystalline Silicon layer), the greater is the horizontal thickness of the spacer dielectric structure used to make the self-aligned gate.

Although the inventive processes, including processes 100, 200, 300, and 400 described below, may be carried out with various silicon substrates, a <100> orientation pure Silicon substrate may advantageously be used, and the structure and process may also be carried out on a different type of substrate and more particularly may be carried out on an unstrained Silicon substrate or on a strained Silicon substrate if greater mobility, greater drive current and greater switching speed and lower power consumption are desired. There is more than one way to achieve strained Silicon.

There are also different locations where strain may be induced and further the strain may be introduced before or after other steps in a fabrication process. In some of the processes and structures described here, the strain in the Silicon substrate when present is achieved by things done to the substrate before fabrication of the CMOS devices starts. In other embodiments described, the strain if present is introduced during the actual semiconductor CMOS fabrication process. These different approaches are described relative to different embodiments of the inventive process and structure formed there from.

Strained Silicon is a Silicon lattice where the Silicon atoms are spaced further apart than they normally are. This lowers the atomic forces that interfere with the movement of charge carriers through the semiconductor lattice. The electrons in strained Silicon can move 70% faster allowing strained Silicon transistors to operate 35% faster in performance. A first way to achieve this is by growing a single crystal Silicon lattice on a substrate of Silicon Germanium SiGe. As the Silicon atoms align with the atoms in the SiGe substrate, they are further apart than they usually are, and this results in strained Silicon. Other ways of achieving strained Silicon substrate are to insert Germanium atoms into the Silicon lattice or add an intermediate layer of Silicon-Germanium compound semiconductor to a substrate under the single crystal Silicon layer. More recent advances include deposition of strained Silicon using metalorganic vapor phase epitaxy (MOVPE) with metalorganics as starting sources, e.g. Silicon sources (silane and dichlorosilane) and Germanium sources (germane, Germanium tetrachloride, and isobutylgermane). The term “strained Silicon substrate” in the claims and in the table below is intended to cover any of these prior art ways of achieving strained Silicon.

There is now described an embodiment for a new process 100 for forming or manufacturing a small MOS transistor with thin Polycrystalline Silicon surface contacts. These small MOS transistors may be CMOS transistors. Embodiments may include a triple well structure. Other embodiments may not include the triple well structure. A triple well isolation structure may be advantageous when complete isolation on both the N-MOS and P-MOS structures are to be isolated as compared to using a double-well structure that may be more suitable when for example only the P-MOS is isolated. Of course the triple-well structure is more complex and more costly to fabricate and may be sufficient for some device applications.

An exemplary structure corresponding to the methods and process now described are illustrated in FIG. 1A for the CMOS device without triple well and in FIG. 1B for the CMOS device including the triple well. Additional alternative embodiments are also described and these alternative embodiments of processes and structures or devices may also provide for triple well and non-triple well structures and devices and the corresponding processes and methods.

The non-limiting exemplary embodiment of process 100 begins by making or providing a doped substrate 10, such as a P-doped substrate 10. The substrate may be prepared as a part of the process 100 or may be obtained from other sources as a starting material. In one non-limiting embodiment, the substrate may be silicon, in another embodiment, the substrate may be a single crystal silicon P-doped substrate, and in another embodiment the substrate may be a <100> crystal orientation of single crystal Silicon P-doped substrate or a strained Silicon substrate. Other substrates may be employed and devices and substrates utilizing different dopants and/or polarities may be implemented. The process can be also carried out on a silicon substrate with a strained Silicon structure, if greater mobility is desired. This is also true of other embodiments of the processes and structures described herein. References to substrates, including for example references to single crystal Silicon substrates, are intended to include but not be limited to particular substrates unless specifically limited, and include but are not limited to either to unstrained or strained substrates achieved in any of the known manners in the prior art.

Shallow Isolation Trenches (STI) 12 are formed (Step 101) to define P-channel and N-channel MOS transistor active areas 16 and 14, respectively, by etching trenches 12 (Step 101a), depositing or otherwise filling CVD Silicon Dioxide 18 to fill trenches (Step 101b), and planarizing by chemically-mechanically polishing Silicon Dioxide back to flush with surface 20 of substrate (Step 101d). In some embodiments, thermal oxide is optionally grown first to line the STI trenches (Step 101c) before filling the trenches with CVD Silicon Dioxide.

In at least some embodiments, the optional growing of the thermal to line the STI trenches (Step 101c) before filling the trenches with CVD Silicon Dioxide is understood as included as one of the ways of filling the Shallow Trench Isolation or STI trenches with Silicon Dioxide.

The above described steps are common to processes for CMOS structures independent of whether they are formed without a triple well or with a triple well. In the alternative embodiment in which a triple well is formed, the process further includes the following steps not needed or used for the non-triple well structure or process. An ion implantation process is performed (Step 102) to form a deep N-well 11 which is large enough to encompass the active areas 14 and 16 of both the P-channel and N-channel CMOS transistors and their respective N-wells 22 and P wells 24 to be formed in the next step of the process. In embodiments where the voltage swing of the logic is not large, and/or chip area budget is tight, the deep N well 11 can be dispensed with and only an N-well 22 in the P-channel device active area is then used with the N-channel device being built in the P doped substrate without a separate P-well 24.

It will therefore be appreciated that two different processes and two different resulting structures may be utilized. The first process and corresponding structure in which the ion implantation process is performed (Step 102) to form a deep N-well 11 which is large enough to encompass the active areas 14 and 16 of both the P-channel and N-channel CMOS transistors and their respective N-wells 22 and P wells 24. The second process and corresponding structure in which an alternate version of the ion implantation process is performed (Step 103Alt) but the deep N-well 11 can be dispensed with and is not formed or present, and only the N-well 22 in the P-channel device active area is used.

Returning again to steps that are common to triple-well and non-triple well embodiments, and with further reference to FIG. 1A and FIG. 1B, process 100 continues with a conventional ion impurity implantation (Step 102) of N-well 22 and P-well 24 within active areas of P-channel and N-channel devices, respectively. In the triple well embodiments (FIG. 1B), the N-wells 22 are implanted within deep N-wells 11 and within active areas of the P-channel devices, and the P-wells 24 are implanted within the deep N-wells 11 and within active areas of the N-channel MOS devices. Impurities, dosage and energy levels are used to achieve the desired transistor characteristics as are known in the art.

Conventional threshold adjustment ion implantations (not shown) may optionally but advantageously be performed (Step 103) in regions of active areas where channels are to be formed to change doping levels so as for example, to adjust threshold voltage.

A thin layer of gate insulator 26 may be grown (Step 104). The gate insulator layer 26 may for example be thermally grown, and may be a layer of insulator comprising Silicon Dioxide. In one non-limiting embodiment, the insulator layer 26 may have a thickness of between approximately 10 Angstroms to 25 Angstroms (for 45-90 nanometer design rules) and in the smaller range of between approximately 10 Angstroms to 12 Angstroms (for 45 angstrom design rules). Smaller design rules may benefit from or require a thickness less than 10-12 Angstroms.

The gate insulator layer 26 is removed (Step 105), such as by masking (Step 105a) and etching (Step 105b), from the area of the surface of substrate in the active area where source and drain polycrystalline surface contacts will make contact with the Silicon, such as with the single crystal Silicon if used.

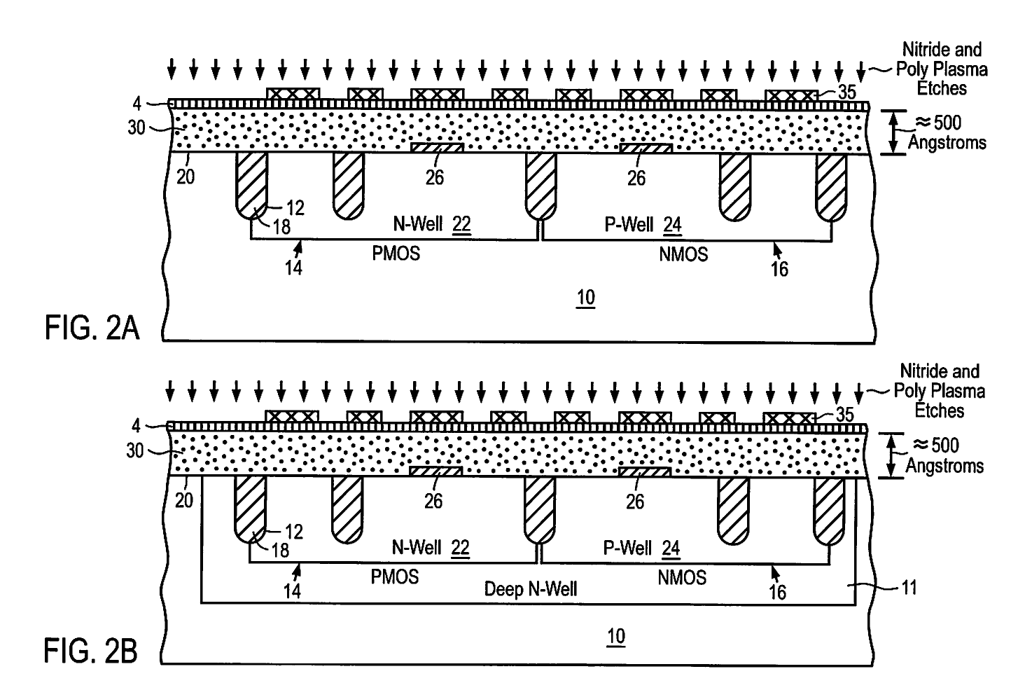

With reference to FIG. 2A and FIG. 2B, next, a layer 30 of Polycrystalline Silicon (polysilicon) is deposited over the entire wafer to a thickness of about 500 Angstroms (Step 106). In one non-limiting embodiment, the Polycrystalline Silicon (polysilicon) layer 30 is advantageously undoped Polycrystalline Silicon (undoped polysilicon). In another non-limiting embodiment, the Polycrystalline Silicon (polysilicon) layer 30 is advantageously doped Polycrystalline Silicon (undoped polysilicon). Polysilicon layers may be etched either before or after doping according different embodiments. Any other thickness which is thinner than the thickness of the polysilicon in the prior art CMOS process can may be used as one of the advantages of the process and resulting structure is to reduce this thickness. Advantageously, the deposition of the polysilicon layer will be substantially less than that required in conventional processes and structures. In one embodiment, this thickness is less than about 1500 Angstrom, in another embodiment less than about 1000 Angstrom, in another embodiment the thickness is less than about 500 Angstrom, in another embodiment between substantially 500 Angstrom and 1000 Angstrom, and in still another embodiment may be between 250 Angstrom and 500 Angstrom. The deposition may be by chemical vapor deposition (CVD) or may be by other deposition process.

A thin layer 4 of Silicon Nitride is optionally but advantageously deposited (Step 107), such as for example by CVD, on top of the Polycrystalline Silicon layer 30 to act as an optional polish stop. Typical thickness of this Silicon Nitride (nitride) layer 4 is about 200 Angstroms, but any thickness that will function to act as an effective polish stop may be used.

A photoresist layer 35 is deposited (Step 108a) and then masked(Step 108b) and developed (Step 108c) to expose photo-lithographically defined regions of the Silicon Nitride layer 4 and underlying Polycrystalline Silicon layer 30 to later be removed to define separate source contacts, drain contacts, gate contacts, and back gate contacts, for each of the NMOS and PMOS devices.

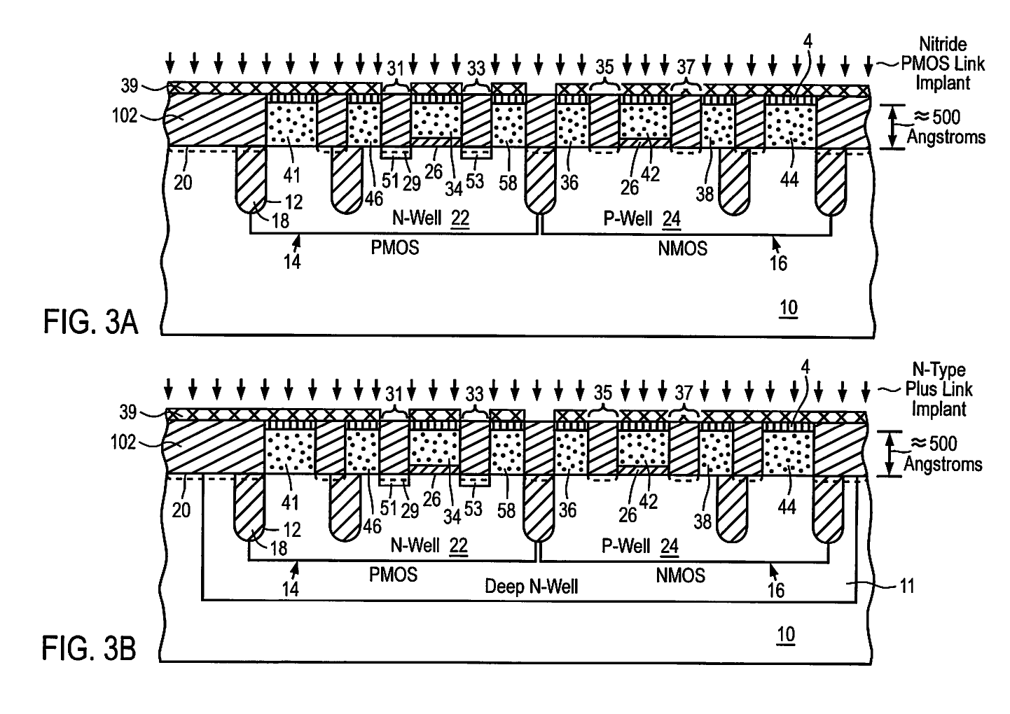

With further reference to FIG. 3A and FIG. 3B, the Silicon Nitride layer 4 is etched away (Step 109a) in the photo-lithographically defined regions exposed from the previous step. Following the Silicon Nitride etch, the Polycrystalline Silicon layer 30 is etched (Step 109b) to define an isolated gate surface contact 34, back gate contact 41, source surface contact 46, and drain surface contact 48 for the PMOS device. This same set of etches (Step 109a and Step 109b) defines for the N-channel transistor an isolated gate surface contact 42, back gate contact 44, source surface contact 36, and drain surface contact 38.

Over-etch occurs by about 10-20% of the thickness of the Polycrystalline Silicon layer. That over-etch can be as much as 100 Angstroms for a 500 angstrom thick Polycrystalline Silicon layer, but is typically only about 50 Angstroms. The amount of over etching may frequently be erratic or at least non-uniform over a wafer or set of wafers, as it is not the same at all positions on the wafer. The over-etch is shown by the dashed lines in FIG. 3A and FIG. 3B of which dashed line 29 is typical. This over-etching is not problematic so long as the Polycrystalline Silicon layer after etching has sufficient thickness and the thickness at any region does not deviate from design or operating requirements.

It may be appreciated in light of the description provide here, that the size and locations of gaps 31, 33, 35 and 37 between the source and drain surface contacts and the gate contact in this new CMOS process are determined photo-lithographically. The size of these gaps can be set at the minimum feature size. This is in contrast to the gate to source or drain gap in the prior art CMOS devices built according to conventional processes.

In the conventional CMOS devices, the horizontal distance between self-aligned gate vertical wall and source and drain regions is not determined photo-lithographically. In the prior art CMOS processes and devices, this gap is the distance between the vertical walls of the gate surface electrode and the inboard (closest to the gate surface contact) edges of the source and drain regions. The inboard edges of the source and drain regions in the prior art CMOS devices are at the outside edges of the spacer dielectric structures formed by an anisotropic etch. This gate-to-source/drain gap distance is a function of the thickness of the Polycrystalline Silicon layer and the properties of the anisotropic etch. This gap is typically about 60 Nanometers, and is larger than the minimum dimension achievable photo-lithographically. This is because the Polycrystalline Silicon layer in the prior art CMOS process is typically 1000 to 1500 Angstroms thick so the spacer material which is anisotropically etched is also typically 1000 to 1500 Angstroms thick.

By comparison, typical gap distance in the new CMOS process devices between the gate surface contact and source and drain contacts is 40 to 45 NM depending upon the design rules, and that gap distance will continue to shrink or decrease when using the new CMOS process as equipment and technique improve to fully utilize the advantages of the new inventive CMOS process and as device dimensions are further scaled downward.

In addition, etching undoped Polycrystalline Silicon in accordance with the new CMOS process and structure leads to better results than the etching of the doped polysilicon layer in the prior art which is 1000-1500 Angstroms thick. However, as described elsewhere herein, various non-limiting embodiments provide for doping first and then etching, or etching first and then doping.

A link region is implanted (Step 110) by masking off the NMOS active area and all the rest of the wafer (Step 110a), but the PMOS link areas are formed by using a developed photoresist layer 39 (Step 110b) and then performing an ion implantation of P-type impurities to heavily dope the link areas 51 and 53 between the gate and the source and drain of the PMOS device (Step 110c) to increase its conductivity.

A separate step to remove photoresist layer 39 (Step 110d) and form a new masking layer (not shown) to expose the NMOS link areas (Step 110e) and then implant them with N-type impurities (Step 110f) is performed next. Typical dosages are 10¹³ to 10¹⁴ with energy typically less than about 10 KEV. These link implants are advantageously made as shallow as possible to help minimize short channel leakage current.

Next, a layer 102 of Silicon Dioxide is deposited (Step 111), such as for example by CVD, over the entire wafer of sufficient thickness to fill the gaps between the surface contacts.

Then, the Silicon Dioxide layer is chemically-mechanically polished back to a state where Silicon Dioxide layer's top surface is flush with the top surface of the Silicon Nitride caps 32 covering the top of each surface contact so as to form a planar surface (Step 112).

The Silicon Nitride caps on each Polycrystalline Silicon surface contact are removed (Step 113).

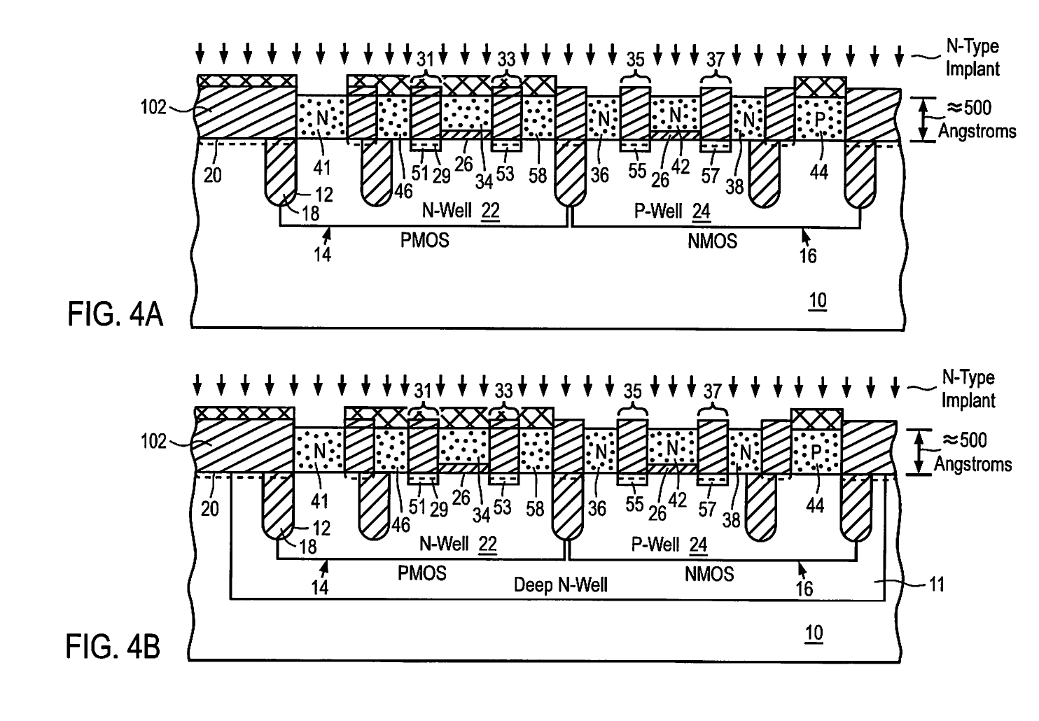

With reference to FIG. 4A and FIG. 4B, a photoresist, mask is then deposited and develop to cover gate, source, and drain surface contacts of the PMOS but to expose the PMOS back gate surface contact 41 and to expose the source 36, drain 38 and gate 42 surface contacts in the NMOS active area but to cover the NMOS back gate contact 44 (Step 114).

Still with reference to FIG. 4A and FIG. 4B, regions of the NMOS and PMOS devices are doped (Step 115), and more particularly the NMOS source (36), drain (38), gate (42) are doped N-type (such as for example, by ion implantation) with Arsenic or some other N-type conductivity enhancing impurity (Step 115a), and PMOS back gate surface contact 41 is doped with an N+ type impurity (Step 115b). Typical dosages are on the order of about 10¹³ to 10¹⁶ and 10-15 KEV energy.

In one embodiment, the Silicon Dioxide between the Polycrystalline Silicon gate surface contact 42 and the substrate advantageously prevents a diode from being formed so the gate surface contact 42 can be doped N type at the same time, and using the same implant mask, which is used to dope the source contact 36 and the drain contact 38 of the NMOS device and the back gate contact 41 of the PMOS device.

However, in another embodiment separate implant masks are used to implant the source and drain contacts of each of the NMOS and PMOS devices separately from the ion implantations of the gate surface contacts of the NMOS and PMOS devices. The gate contact of the NMOS device can be doped with the same impurity type as the source and drain contacts of the NMOS device (N+) or it can be doped the opposite polarity (P+) since no diode is formed between the gate contact and the substrate and no gate current flows. It is only necessary to make the gate contact conductive. Likewise, the gate contact of the PMOS device may be doped with the same impurity type as the source and drain contacts of the PMOS device (P+), or it can be doped the opposite polarity (N+) since no diode is formed between the gate contact and the substrate and no gate current flows. It is only necessary to make the gate contact conductive. The separate implants of the source and drain surface contacts from the gate surface contact may be preferred so that the doping profile of the source and drain regions under the source and drain contacts can be controlled to achieve desired transistor characteristics by separately controlling the doping profile of these regions (junction depth, impurity concentration, impurity distribution throughout the regions) when desired or advantageous to do so.

A photoresist, mask is deposited and develop to cover NMOS active area except for the NMOS back gate 44, and the source surface contact 46, gate surface contact 34 and drain surface contact 48 of the PMOS active area are exposed (Step 116). (This masking step is not shown in the figures.)

An ion implantation of P-type conductivity enhancing impurity is performed (Step 117) to dope PMOS source Polycrystalline Silicon surface contact 46, drain Polycrystalline Silicon surface contact 48, gate Polycrystalline Silicon surface contact 34, and back gate Polycrystalline Silicon surface contact 44 to be P type. Typical dosages are one the order of about 10¹³ to 10¹⁶ and using an implant energy of about 10-15 KEV. As earlier described, recall that source, drain and gate surface contacts may all be doped simultaneously or separately.

A anneal and thermal drive-in processing step is performed to cause impurities from the overlying Polycrystalline Silicon source and drain contacts to diffuse into the underlying substrate to form self-aligned source and drain regions (Step 118). In the PMOS device, the source region formed by this drive-in step is source region 48 and the drain region is drain region 50 with link regions 51 and 53 coupling these source and drain regions to the channel region under the gate oxide. In the NMOS device, the source region is source region 52 and the drain region is drain region 54 with link regions 55 and 57 coupling these regions to the channel region under the gate oxide.

This anneal process step also anneals implanted impurities in Polycrystalline Silicon and causes impurities from the back gate contacts to diffuse into the substrate to form ohmic contacts 61 and 63. Typical temperatures for this anneal and drive in range from substantially 900-1200 degrees C. for a time interval from about 5 seconds to about 1 millisecond, and possibly being any time interval or value between these values.

This short anneal time forms very shallow source and drain regions thereby reducing short channel leakage and reducing power consumption. There is no need for a deeper source and drain region as in the prior art CMOS process because no silicide is being formed on the surface of the substrate.

In the prior art CMOS process, silicide was formed on the surface of the substrate at the source and drain regions. This silicide in the prior art CMOS structure could extend down into the source and drain regions far enough to short out the junctions of the source and drain regions with the well. Therefore, in the prior art CMOS process, the source and drain implants need to be deeper so that the silicide formed on the surface of the source and drain regions does not extend down into the substrate far enough to short out these junctions. In contrast, in the new process, the silicide 59 is formed on the top surfaces of the surface contacts and never comes into contact with the substrate anywhere.

It may be further noted, that the doped polysilicon surface contacts can be extended outside the active across the STI Silicon Dioxide field to make contact with other device terminals formed on the same wafer so as to form poly-level interconnects.

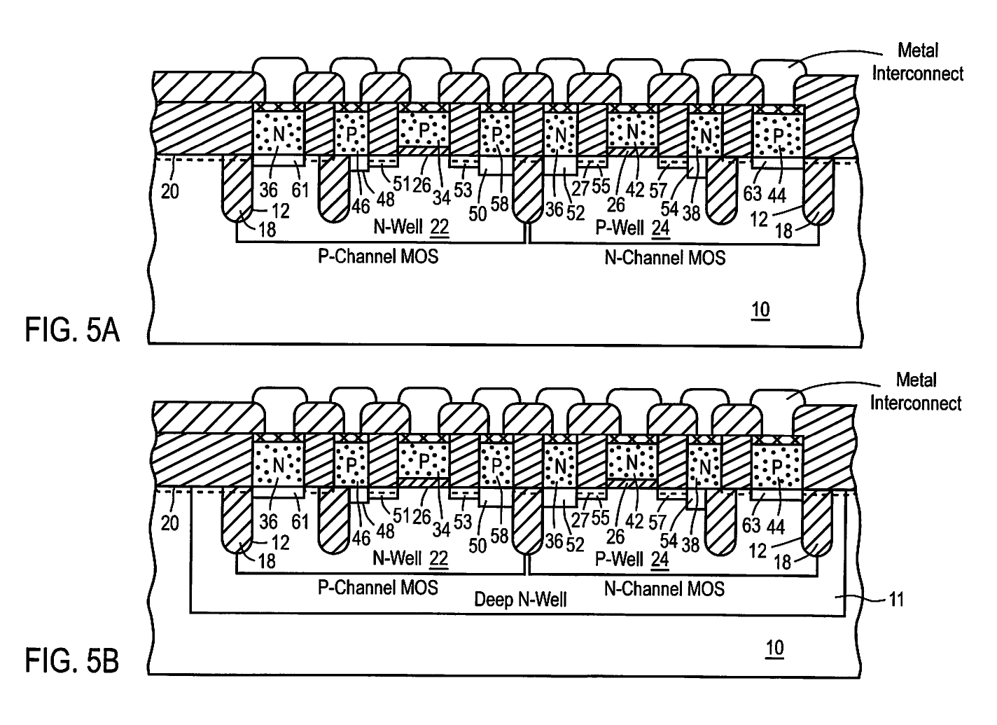

With reference to FIGS. 5A and 5B, silicide is formed on top of all Polycrystalline Silicon surface contacts (Step 119) by depositing an appropriate silicide producing material or metal, such as for example Titanium, Cobalt or Nickel (Step 119a) and heating the structure to about 600 degrees C. for a short time (Step 119b), and then dipping off the metal which has not been converted to silicide (Step 119c).

The rest of the process to deposit an insulation layer (Step 120), form contact holes therein (Step 121), and deposit and etch metal to form interconnects (Step 122) is conventional and not described in greater detail here.

### Exemplary Embodiment of Device and Poly-First Manufacturing Process for Small MOS Transistor With Thin Polycrystalline Silicon Doped Before Etching to form Surface Contacts Polycrystalline Silicon is Doped Before it is Etched to form Surface Contacts

In an alternative embodiment of the process 200, the polysilicon is doped before it is etched to form the source, gate and drain contacts. The process has some similarities but also differences from the above described process 100 where the polysilicon is not doped before it is etched to form the source, gate, and drain contacts. In this exemplary process 200 the polycrystalline silicon is doped before it is etched to form surface contacts, as compared to process 100 above the polycrystalline silicon is not doped before it is etched.

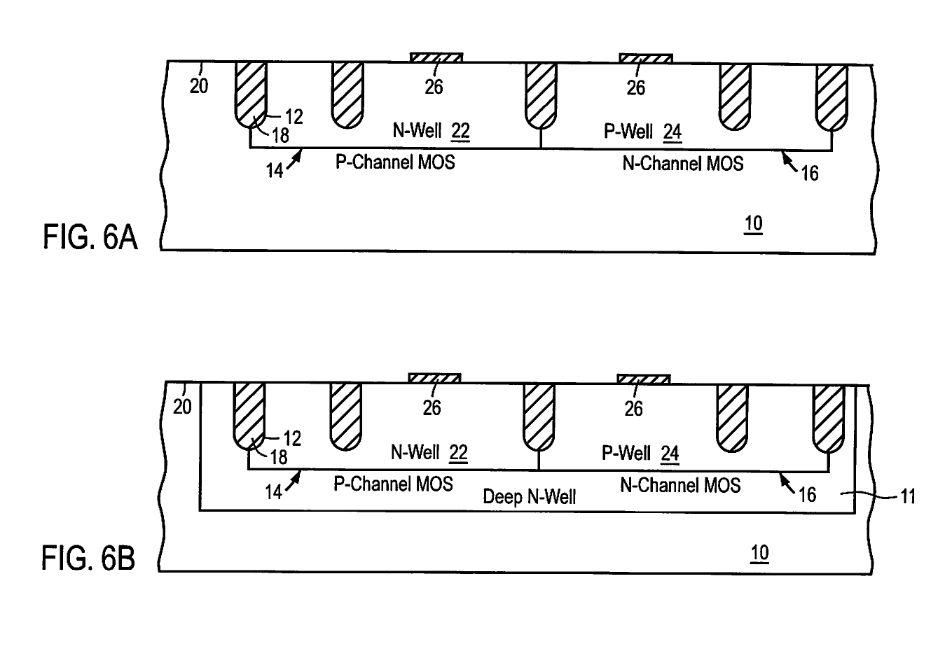

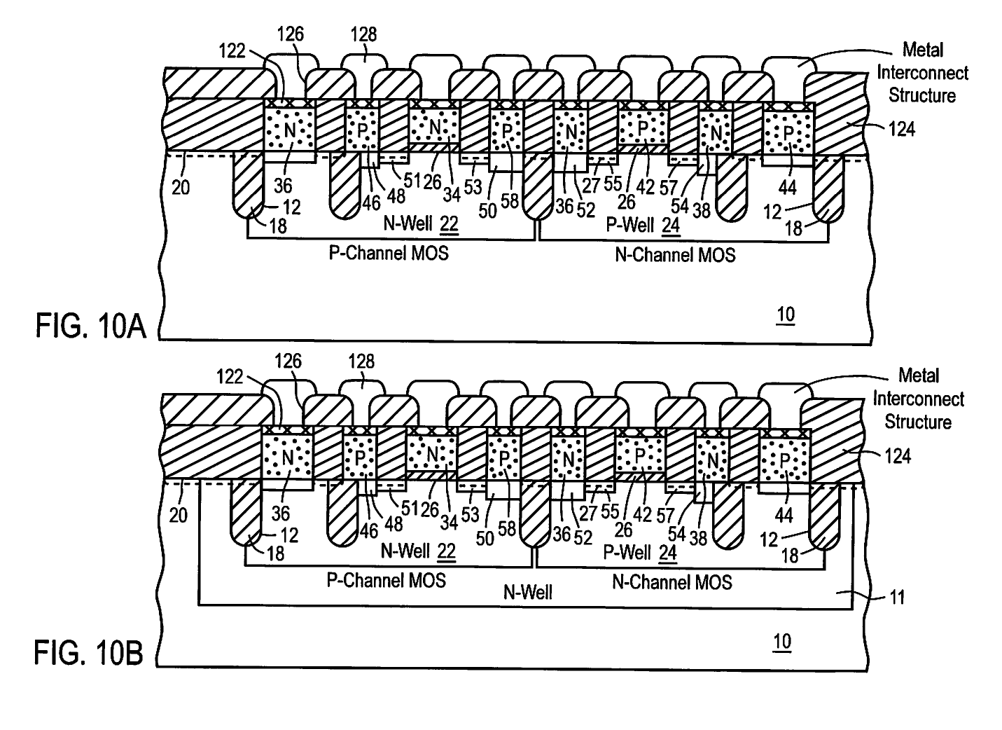

This alternative embodiment of the process and corresponding structure is now described with respect to FIG. 6A-6B through 10A-10B. One resulting exemplary transistor structure for a small MOS transistor made according to this alternative process 200 is also referred to as the “poly first” transistor embodiment and is illustrated in FIG. 10B but in this embodiment the polycrystalline silicon is doped before it is etched to form surface contacts.

The resulting transistor structure for a small MOS transistor made according to an embodiment of the process shown and described relative to the embodiment in FIG. 10B.

As for the embodiment of the process 100 described herein above, this non-limiting exemplary embodiment of process 200 begins by making or providing a doped substrate 10, such as a P-doped substrate 10. The substrate may be prepared as a part of the process 200 or may be obtained from other sources as a starting material. In one non-limiting embodiment, the substrate may be silicon, in another embodiment, the substrate may be a single crystal silicon P-doped substrate, and in another embodiment the substrate may be a <100> crystal orientation of single crystal Silicon P-doped substrate or a strained Silicon substrate. Other substrates may be employed and devices and substrates utilizing different dopants and/or polarities may be implemented. References to substrates, including for example references to single crystal Silicon substrates, are intended to include but not be limited to particular substrates unless specifically limited, and include but are not limited to either to unstrained or strained substrates achieved in any of the known manners in the prior art.

Shallow Isolation Trenches 12 are formed (Step 201) to define P-channel and N-channel MOS transistor active areas 16 and 14, respectively, by etching trenches 12 (Step 201a), depositing or otherwise filling CVD Silicon Dioxide 18 to fill trenches (Step 201b), and planarizing by chemically-mechanically polishing Silicon Dioxide back to flush with surface 20 of substrate (Step 201d).

In some embodiments, thermal oxide is optionally grown first to line the STI trenches (Step 201c) before filling the trenches with CVD Silicon Dioxide. In at least some embodiments, the optional growing of the thermal to line the STI trenches (Step 201c) before filling the trenches with CVD Silicon Dioxide is understood as included as one of the ways of filling the Shallow Trench Isolation or STI trenches with Silicon Dioxide.

As described relative to an earlier embodiment of the structure and process, in embodiments where the voltage swing of the logic is not large and chip area budget is tight, the deep N well 11 of the embodiment of FIG. 6B can be dispensed with and only an N well 22 in the P-channel device active area is used with the N-channel device being built in the P doped substrate without a separate P well 24. However, a P-well 24 in the P-substrate is preferred to allow the doping profile of the P-well to be controlled to achieve the desired transistor characteristics.

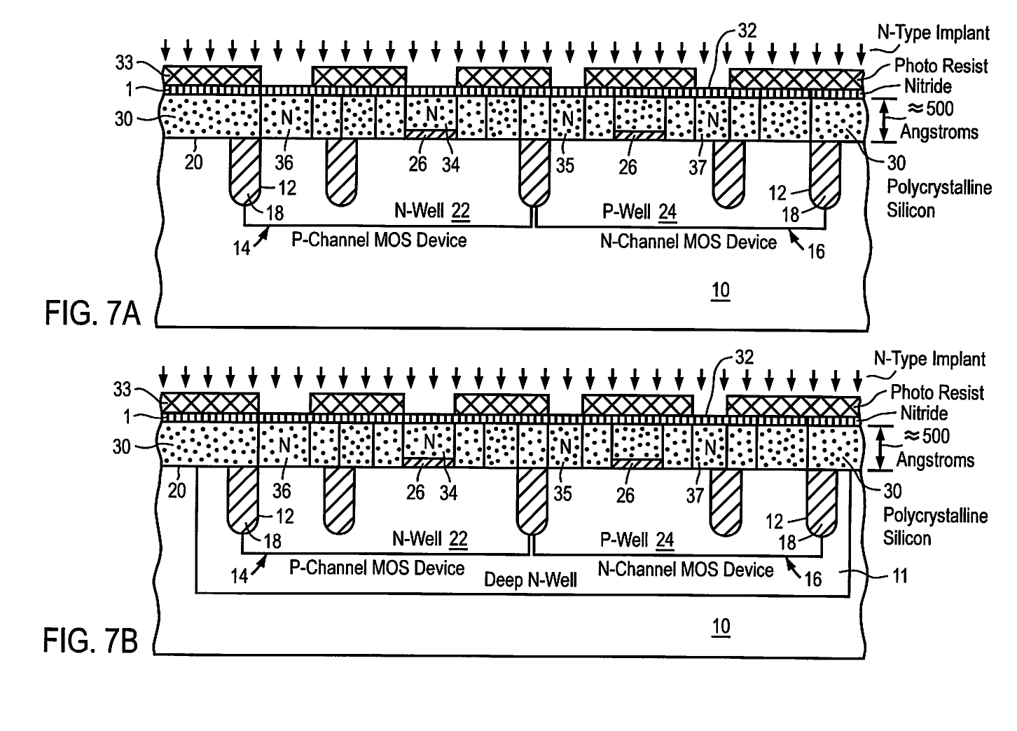

With further reference to FIG. 7A and FIG. 7B, process 200 continues with ion implantation (Step 202), including ion implantation of N-well 22 within active areas of P-channel devices (Step 202a) and ion implantation of P-well 24 within active areas of N-channel MOS devices (Step 202b). In the triple well embodiments (FIG. 6B), the N-wells 22 are implanted within deep N-wells 11 and within active areas of the P-channel devices, and the P-wells 24 are implanted within the deep N-wells 11 and within active areas of the N-channel MOS devices. Impurities, dosage and energy levels are used to achieve the desired transistor characteristics.

Conventional threshold adjustment ion implantations (not shown) may optionally but advantageously be performed (Step 203) in regions of active areas where channels are to be formed to change doping levels so as for example, to adjust threshold voltage.

A thin layer of gate insulator 26 may be grown (Step 204) as illustrated. The gate insulator layer 26 may for example be thermally grown, and may be a layer of insulator comprising Silicon Dioxide. In one non-limiting embodiment, the insulator layer 26 may have a thickness of between approximately 10 Angstroms to 25 Angstroms (for 45-90 nanometer design rules) and in the smaller range of between approximately 10 Angstroms to 12 Angstroms (for 45 angstrom design rules). Smaller design rules may benefit from or require a thickness less than 10-12 Angstroms.

The gate insulator layer 26 is removed (Step 205), such as by masking (Step 205a), and etching (Step 205b), from the area of the surface of substrate in the active area where source and drain surface contacts will make contact with the Silicon, such as with the single crystal Silicon if used.

With reference to FIG. 7A and FIG. 7B, next, a layer 30 of Polycrystalline Silicon (polysilicon) is deposited to a thickness of about 500 Angstroms (Step 206). This layer covers the gate insulator and covers the exposed Silicon of the active area. Any other thickness which is thinner than the thickness of the polysilicon in the prior art CMOS process can may be used as one of the advantages of the process and resulting structure is to reduce this thickness. Advantageously, the deposition of the polysilicon layer will be substantially less than that required in conventional processes and structures. In one embodiment, this thickness is less than about 1500 Angstrom, in another embodiment less than about 1000 Angstrom, in another embodiment the thickness is less than about 500 Angstrom, in another embodiment between substantially 500 Angstrom and 1000 Angstrom, and in still another embodiment may be between 250 Angstrom and 500 Angstrom. Advantageously, the vertical height of the layer of thickness will be about the same as the horizontal feature size according to the line width or design rules being used. For example for 65 nm design rules and horizontal feature sizes, the Polysilicon layer will be about 65 nm (650 Angstrom) thick; for 45 nm design rules and horizontal feature sizes, the Polysilicon layer will be about 45 nm (450 Angstrom) thick, for 32 nm design rules and horizontal feature sizes, the Polysilicon layer will be about 32 nm (320 Angstrom) thick, and so on so that the ratio of the thickness to the horizontal dimension of for example the source, drain, and gate surface contacts is about 1.0. Tolerances or variation from unity of at least ±20% may be used, more advantageously less than ±10%, and more advantageously less than about ±5%. The deposition may be by chemical vapor deposition (CVD) or may be by other deposition process.

A thin layer of Silicon Nitride is optionally but advantageously deposited (Step 207), such as for example by CVD, on top of the Polycrystalline Silicon layer 30 to act as an optional polish stop. Typical thickness of this Silicon Nitride (nitride) layer 1 is about 200 Angstroms, but any thickness that will function to act as an effective polish stop may be used.

It may be appreciated that some portions and steps of the process 200 are similar or the same as those in process 100 while others differ. Additional differences are including the process steps that follow.

A photoresist layer 33 is deposited (Step 208a) and then masked (Step 208b) and developed (Step 208c) to cover all of Polycrystalline Silicon layer 30 except the areas where the polysilicon is to be doped N-type. It may be appreciated that in CMOS devices, the gate polysilicon may be doped with the same impurity types as the source and drain surface contacts since the gate surface contacts do not contact the underlying substrate so no PN junction will be formed under the gate surface contact and the gate surface contact only need to be rendered conductive.

N-type impurities are implanted (Step 209) to dope the gate surface contact 34 and the back gate surface contact 36 of the P-channel MOS transistor heavily N-type (Step 209a), and to dope the source surface contact 35 and the drain surface contact 37 of the N-channel MOS transistor heavily N-type (Step 209b).

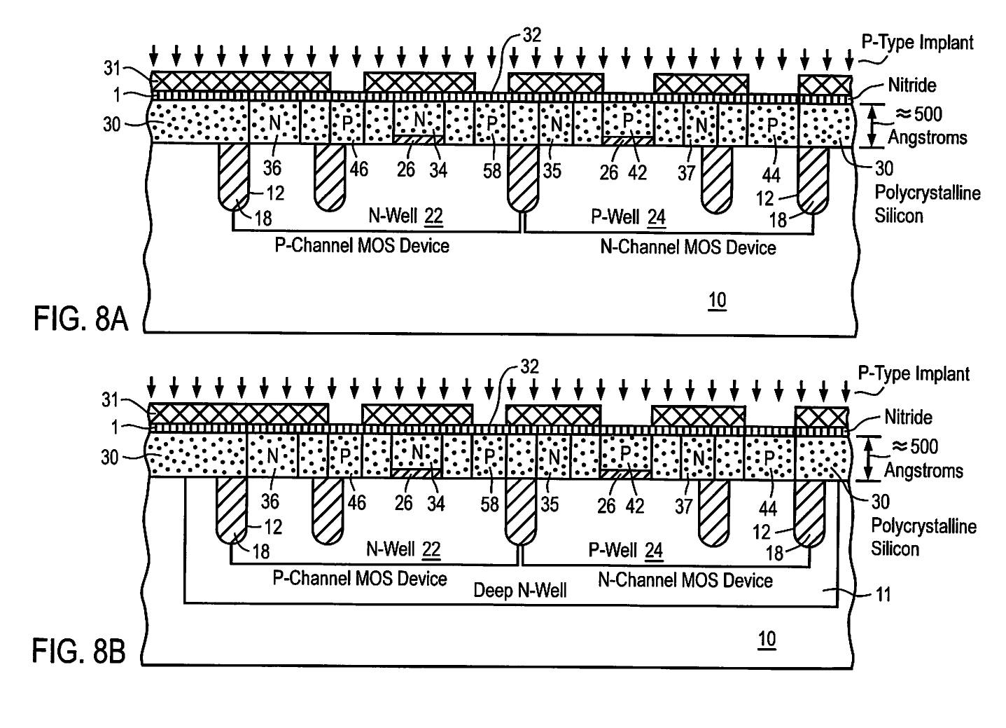

With reference to FIG. 8A and FIG. 8B, photoresist layer 33 (deposited to cover all of Polycrystalline Silicon layer 30 except the areas where the polysilicon is to be doped N-type) is then removed (Step 210a), and a photoresist layer 31 deposited (Step 210b), masked (Step 210c) and developed (Step 210d) to cover all of Polycrystalline Silicon layer 30 except the areas where the gate surface contact 42 and the back gate surface contact 44 are to be formed over active area of the N-channel MOS device and except for the areas where the source surface contact 46 and the drain surface contact 48 are to be formed over the P-channel MOS device.

P-type impurities are implanted (Step 211), for example using Ion Implantation, to dope the gate surface contact 42 and the back gate surface contact 44 of the N-channel MOS transistor heavily P-type (Step 211a), and to dope the source surface contact 46 and the drain surface contact 48 of the P-channel MOS transistor heavily P-type (Step 211b).

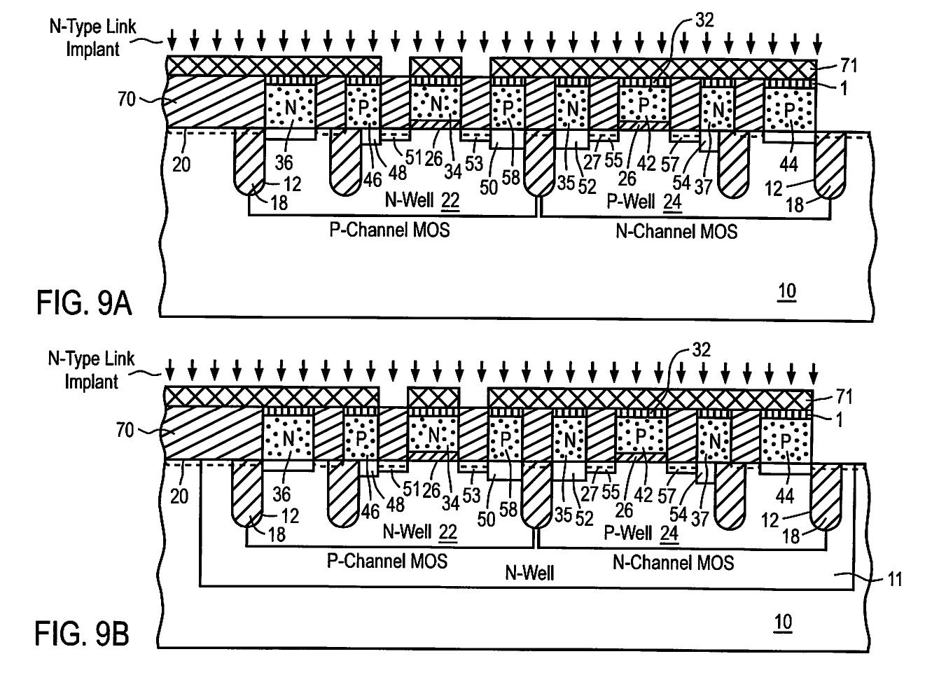

With reference to FIG. 9A and FIG. 9B, photoresist layer 35 is removed (Step 212a), and a new photoresist layer (not shown) is deposited (Step 212b), masked (Step 212c), and developed (Step 212d). The Silicon Nitride layer 1 is then etched (Step 212e) and then the Polycrystalline Silicon layer 30 is etched (Step 212f) to define for the P-channel transistor an isolated gate surface contact 34, back gate contact 36, source surface contact 46 and drain surface contact 48. This same set of etches defines for the N-channel transistor an isolated gate surface contact 42, back gate contact 44, source surface contact 35, and drain surface contact 37.

It may be appreciated that over-etching may typically occur by about 10-20% of the thickness of the Polycrystalline Silicon layer. That over-etch can be as much as 100 Angstroms for a 500 angstrom thick Polycrystalline Silicon layer, but is typically about 50-60 Angstroms. It is erratic or at least non-uniform as it is not the same at all positions on the wafer. The over-etching is shown by the dashed lines of which dashed line 29 is typical.

The gap between the source and drain surface contacts and the gate surface contact in the new CMOS process described here is determined photolithographically. The size of this gap can therefore be set at the minimum feature size.

This is in contrast to the same gap in the conventional CMOS devices built according to the conventional process. In the conventional CMOS devices, the horizontal distance between self-aligned gate vertical wall and source and drain regions is not determined photolithographically. This gap is the distance in the conventional CMOS devices between the vertical walls of the gate surface electrode and the inboard (closest to the gate surface contact) edges of the source and drain regions. The inboard edges of the source and drain regions in the conventional CMOS devices are at the outside edges of the spacer dielectric structures formed by an anisotropic etch. This gate-to-source/drain gap distance is a function of the thickness of the Polycrystalline Silicon layer and the properties of the anisotropic etch. This gap in conventional devices and structures is larger than the minimum dimension achievable photolithographically because the Polycrystalline Silicon layer is typically 1000 to 1500 Angstroms thick. Typical gap distance in the conventional CMOS device is 60 nanometers. Typical gap distance in the new CMOS process devices between the gate surface contact and source and drain contacts is 40 to 45 nm depending upon the design rules and that distance will continue to shrink as equipment and processes improve and device dimensions are further scaled downward.

A Silicon Dioxide layer 70 is deposited, such as by using CVD, over the entire wafer of sufficient thickness to fill the gaps between the surface contacts (Step 213).

The Silicon Dioxide layer 70 deposited (See step 213) is polished back (for example, using chemically-mechanically polishing), to a state where the Silicon Dioxide layer 70 top surface is flush with the top surface of the Silicon Nitride layer 1 covering the top of each surface contact so as to form a planar surface (Step 214).

A photoresist layer 71 is deposited (Step 215a), masked (Step 215b) and developed (Step 215c) to expose the link areas 51 and 53 of the P-channel MOS transistor and to cover the active area of the N-channel MOS transistor (Step 215)

N-type impurity ion are implanted (Step 216), such as by using ion implantation, to form highly doped link regions 51 and 53 between source and drain regions to be formed (in subsequent process steps) and channel in P-channel MOS transistor

The old photoresist layer 71 is removed (Step 217a) and a new photoresist layer (not shown) is deposited (Step 217b), masked (Step 217c). and developed (Step 217d) to expose the link areas 55 and 57 of the N-channel MOS transistor and to cover the active area of the P-channel MOS transistor (Step 217).

P-type impurities are then implanted (Step 218), such as by ion implantation, to form highly doped link regions 55 and 57 between source and drain regions (to be formed in subsequent steps) and channel in N-channel MOS transistor.

A combination thermal drive in (Step 219a) and anneal step (Step 219b) is performed to anneal the implanted link area impurities and to drive impurities by diffusion from the source and drain surface contacts of both the P-channel and N-channel MOS devices into the underlying single crystal Silicon. This drive-in step also forms ohmic contacts under the back gate surface contacts 36 and 44. The drive-in step forms self-aligned source region 48 and drain region 50 of the P-channel MOS transistor, and forms self-aligned source region 52 and drain region 54 of the N-channel MOS transistor.

With reference to FIG. 10A and FIG. 10B, all photoresist and Silicon Nitride is removed from the tops of the surface contacts of both the N-channel and P-channel MOS transistors (Step 220).

Silicide (of which 122 is typical) is then formed (not shown)on tops of the Polycrystalline Silicon surface contacts where nitride layer had been present (Step 221).

Finally, an insulation layer 124 is deposited over entire wafer (Step 222a), contact openings (of which 126 is typical) etched over at least some of the surface contacts previously formed to expose the silicide layer on top of each contact (Step 222b), a layer of metal deposited to fill contact openings (Step 222c), and the metal etched (Step 222d) to form desired interconnects (of which 128 is typical).

### Exemplary Embodiment of Device and Manufacturing Process for MOS Transistor Using Differential Thermal Expansion/Contraction Between Silicon and Silicon Nitride to Introduce Strain and Provide for Higher Carrier Mobility

Attention is next directed the description of an exemplary process 300 to fabricate strained silicon MOS transistors, including CMOS transistors, having higher mobility and higher resulting drain current and higher switching speed at least partially the result of the new structure and the incorporation of strained silicon. The exemplary process makes a strained Silicon CMOS transistor where the strain is achieved by deposition of a Silicon Nitride layer on the surface of the substrate under predetermined conditions during the actual process of fabrication of the CMOS transistors. The strain is caused by differential thermal expansion rates between Silicon and Silicon Nitride. Other methods and/or materials for introducing strain may alternatively be used.

Recall that the exemplary embodiments described hereinabove each teach use of a silicon substrate that may be either a strained Silicon substrate or an unstrained Silicon substrate where the strain in the Silicon substrate when present is achieved by things done to the substrate before fabrication of the CMOS devices starts, not during the actual CMOS fabrication process as described. Such pre-fabrication strain inducing steps may for example include or be selected from things such as fabricating the Silicon substrate out of a Silicon-Germanium alloy, and/or other techniques known in the art. Electrons flow up to 70% faster in strained silicon which makes transistors built in strained silicon up to 35% faster.

This alternative embodiment of a process 300 is common to the process for process 100 up through and including Step 109. Briefly that process provides for starting with a substrate, such as an unstrained Silicon substrate which is P doped. Process 100 steps through 109 are performed to result in forming polysilicon surface contacts separated by gaps on an unstrained Silicon substrate. The gate surface contact 34 is separated from the source and drain surface contacts 46 and 48 by gaps 31 and 33 and 35 and 37 which are photo-lithographically determined. These earlier steps are conveniently renumbered from process 100 steps to process 300 steps without repeating them here. For example, process 100 step 109 is referred to for convenience as process 300 step 309.

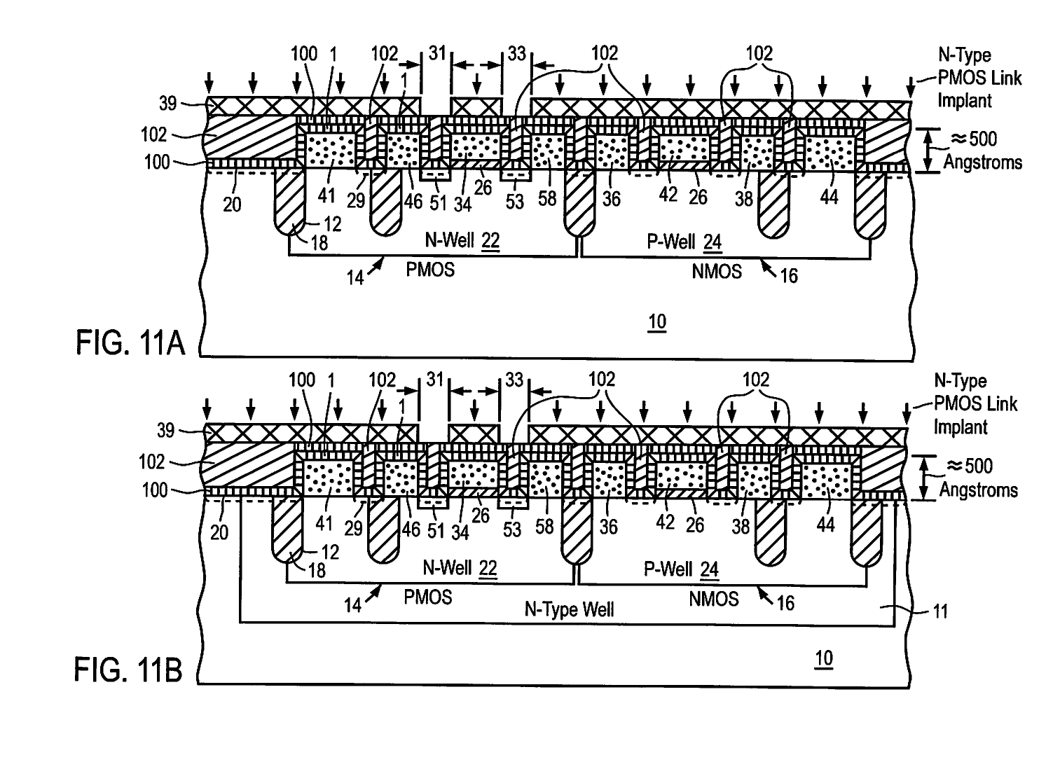

With reference to FIG. 11 the Polycrystalline Silicon layer 30 is etched (Step 310a) to form separate source, gate, drain and back gate contacts for PMOS and NMOS devices (41, 46, 34, 48, 36, 42, 38, 44). Alternative embodiments of a structure that does not include a triple-well isolation structure also referred to as a double-well (without deep N-well) and a triple-well isolation structure (with deep N-well) are illustrated in FIG. 11A and FIG. 11B, respectively.

Next, a thin layer of Silicon Nitride 100 is deposited (Step 310b) under predetermined conditions known in the prior art to create a strained Silicon Nitride layer over the entire wafer, or at least over the areas of the wafer where active devices will be formed. Silicon Nitride layer 100 adds to the thickness of the Silicon Nitride caps 1 which were formed when the Polycrystalline Silicon layer 30 (recall FIG. 2B) with its Silicon Nitride cap 1 was etched to form separate surface contacts. The differential rates of thermal contraction between silicon substrate, such as a single crystal Silicon substrate, and Silicon Nitride puts the silicon substrate, such as the single crystal Silicon substrate, into strain which increases its mobility.

With reference to FIG. 11, a link region is implanted (Step 311a) by masking off the NMOS active area and all the rest of the wafer but the PMOS link areas by developed photoresist layer 39, and then doing an ion implantation of N-type impurities to heavily dope the link areas 51 and 53 between the gate and the source and drain of the PMOS device to increase its conductivity.

A separate step (Step 311b) to remove photoresist layer 39 and form a new masking layer (not shown) to expose the NMOS link areas and then implant them with P-type impurities is performed next. Typical implant impurity dosages are on the order of about 10¹³ to 10¹⁴ with energy less than about 10 KEV. These link implants should be as shallow as possible to help minimize short channel leakage current.

A layer of Silicon Dioxide 102 is then deposited (Step 312a) over the entire wafer to a thickness to fill the gaps between the Polycrystalline Silicon surface contacts, and then polished back (Step 312b) to the top of Silicon Nitride layer 100, such as by chemical-mechanical polishing.

The remainder of the process 300 for Fabricating Strained Silicon CMOS Transistors with Higher Mobility and Higher Resulting Drain Current And Higher Switching Speed are identified here for convenience as Step 313 (even though it includes multiple steps) is the same as described for process 100. These steps involve: removing the Silicon Nitride caps from the tops of the surface contacts, masking for the N-type implant and performing an N-type implant to dope the Polycrystalline Silicon surface contacts of the PMOS and NMOS devices that need to be N-type; masking for the P-type implant and performing a P-type implant to dope the Polycrystalline Silicon surface contacts of the PMOS and NMOS devices that need to be P-type; then performing a final anneal and thermal drive-in to form the source and drain areas of the PMOS and NMOS devices and the ohmic contacts for the back gate contacts; and then forming silicide on the tops of all surface contacts.

### Exemplary Embodiment of Device and Silicon Dioxide-First Manufacturing Process for Small MOS Transistor With Thin Polycrystalline Silicon Surface Contacts

Attention is now directed to a further alternative embodiment referred to as the “silicon dioxide first” or more simply the “oxide first” embodiment for forming MOS, including CMOS semiconductor devices and transistors. This process and the corresponding structure advantageously help to overcome issues that might arise associated with the formation of very thin Polycrystalline Silicon (polysilicon) surface contacts on the order of about 500 Angstroms or less. These polysilicon surface contacts are described elsewhere herein.

This process forms the Polycrystalline Silicon surface contacts by first depositing a layer of thin Silicon Dioxide (oxide) which has the thickness of the desired thickness for the Polycrystalline Silicon surface contacts. A layer of Silicon Nitride (nitride) is then deposited on top of the oxide to act as a polish stop layer. Openings where the desired surface contacts are to be formed are then etched in the nitride and oxide layers, and polysilicon is deposited and polished back to be flush with the top of the silicon nitride layer. This creates multiple separate surface contacts which are then suitably masked and suitably doped by ion implantation. A thermal drive-in then creates self-aligned source and drain regions under the source and drain surface contacts.

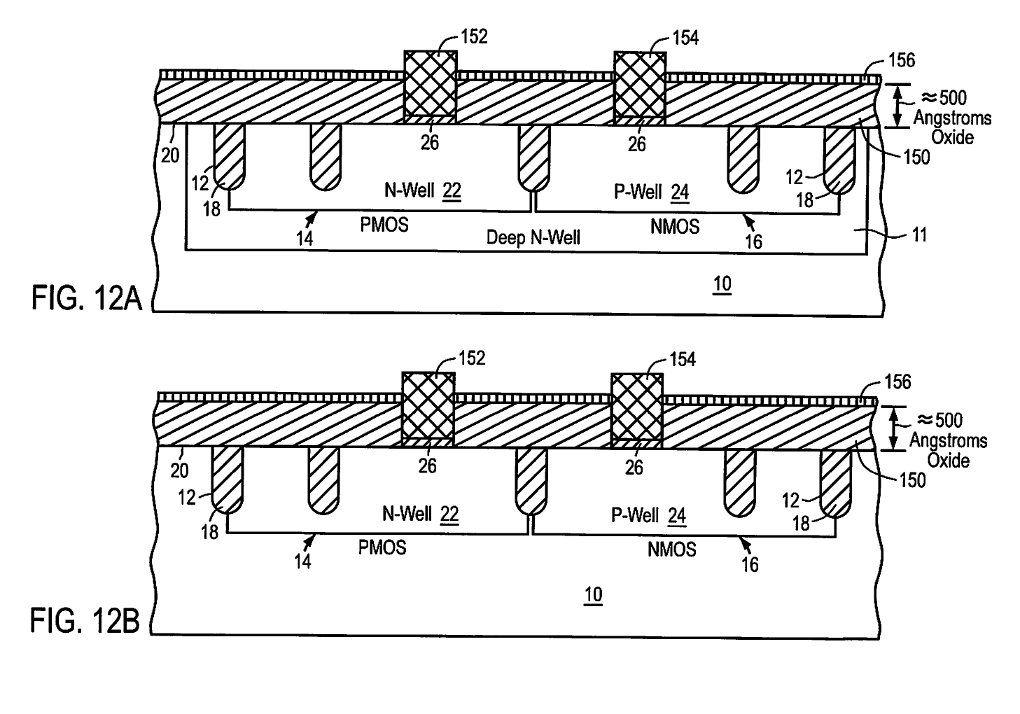

The details of an exemplary embodiment are now described with reference to the structures illustrated in FIG. 12A-12B through 16A-16B.

With further reference to FIG. 12A, as for the embodiment of the process 100 described herein above, this non-limiting exemplary embodiment of process 400 begins by making or providing a doped substrate 10, such as a P-doped substrate 10. The substrate may be prepared as a part of the process 400 or may be obtained from other sources as a starting material. Substrates may be strained or unstrained substrates. In one non-limiting embodiment, the substrate may be silicon, in another embodiment, the substrate may be a single crystal silicon P-doped substrate, and in another embodiment the substrate may be a <100> crystal orientation of single crystal Silicon P-doped substrate or a strained Silicon substrate. Other substrates may be employed and devices and substrates utilizing different dopants and/or polarities may be implemented. References to substrates, including for example references to single crystal Silicon substrates, are intended to include but not be limited to particular substrates unless specifically limited, and include but are not limited to either to unstrained or strained substrates achieved in any of the known manners in the prior art.

Shallow Isolation Trenches 12 are formed (Step 401) to define P-channel and N-channel MOS transistor active areas 16 and 14, respectively, by etching trenches 12 (Step 401a), depositing or otherwise filling CVD Silicon Dioxide 18 to fill trenches (Step 401b), and planarizing by chemically-mechanically polishing Silicon Dioxide back to flush with surface 20 of substrate (Step 401d).

In some embodiments, thermal oxide is optionally grown first to line the STI trenches (Step 401c) before filling the trenches with CVD Silicon Dioxide. In at least some embodiments, the optional growing of the thermal to line the STI trenches (Step 401c) before filling the trenches with CVD Silicon Dioxide is understood as included as one of the ways of filling the Shallow Trench Isolation or STI trenches with Silicon Dioxide.

Process 400 continues with an ion implantation (Step 401e) to form a deep N-well 11 which is large enough to encompass the active areas 14 and 16 of both the P-channel and N-channel CMOS transistors and their respective shallower N-wells 22 and P-wells 24 to be formed in a subsequent process step.

In embodiments where the voltage swing of the logic is not large and chip area budget is tight, the deep N-well 11 may be dispensed with and only an N-well 22 in the P-channel device active area is used with the N-channel device being built in the P-doped substrate without a separate P-well 24, as already described relative to certain other embodiments.

In an alternative embodiment illustrated in FIG. 12B, a structure without the deep N well 11 is formed using the same steps as above, but no deep N-well implantation is done.

N-well 22 and P-well 24 are implanted (Step 402), such as by using conventional ion implantation, within active areas of P-channel and N-channel MOS devices, respectively. In the FIG. 12A embodiment, both the P well and the N well are implanted so as to be contained within deep N well 11. Impurities, dosage and energy levels are used to achieve a doping profile for each well needed for whatever transistor characteristics are desired, and know conventional techniques and processes may be used.

Conventional threshold adjustment ion implantations (not shown) may be performed (Step 403) in regions of active areas where channels are to be formed to change doping to adjust threshold voltage as described relative to other embodiments described herein.

A thin layer of gate insulator 26 is grown, such as by thermally growing. The gate insulator layer 26 may for example be thermally grown, and may be a layer of insulator comprising Silicon Dioxide. In one non-limiting embodiment, the insulator layer 26 may have a thickness of between approximately 10 Angstroms to 25 Angstroms (for 45-90 nanometer design rules) and in the smaller range of between approximately 10 Angstroms to 12 Angstroms (for 45 angstrom design rules). Smaller design rules may benefit from or require a thickness less than 10-12 Angstroms.

The gate insulator is removed (Step 405) from area of surface of substrate in active area where source and drain polycrystalline surface contacts will make contact with the single crystal silicon by masking (Step 405a) and etching (Step 405b). The photoresist blocking layers 152 and 154 protect the gate oxide. They are advantageously left in place during the next step to prevent the CVD oxide layer 150 from covering up the gate oxide 26.

A layer 150 of Silicon Dioxide (oxide) is deposited (Step 406) over the entire wafer to a thickness of about 100-900 angstroms, preferably about 500 Angstroms, using for example CVD processes.

As in other embodiments described herein, Any other thickness which is thinner than the thickness of the polysilicon in the prior art CMOS process can may be used as one of the advantages of the process and resulting structure is to reduce this thickness. Advantageously, the deposition of the polysilicon layer will be substantially less than that required in conventional processes and structures. In one embodiment, this thickness is less than about 1500 Angstrom, in another embodiment less than about 1000 Angstrom, in another embodiment the thickness is less than about 500 Angstrom, in another embodiment between substantially 500 Angstrom and 1000 Angstrom, and in still another embodiment may be between 250 Angstrom and 500 Angstrom. The deposition may be by chemical vapor deposition (CVD) or may be by other deposition process.

Next, a thin layer 156 of Silicon Nitride (nitride) is deposited (Step 407), such as by CVD, on top of the Silicon Dioxide layer 50 to act as a polish stop. Typical thickness of this nitride layer may be about 200 angstroms, but any thickness that will function to act as an effective polish stop may be used. This leaves an oxide/nitride film of the desired thickness of the surface contacts covering the surface everywhere except where the photoresist barrier over the gate oxide is formed.

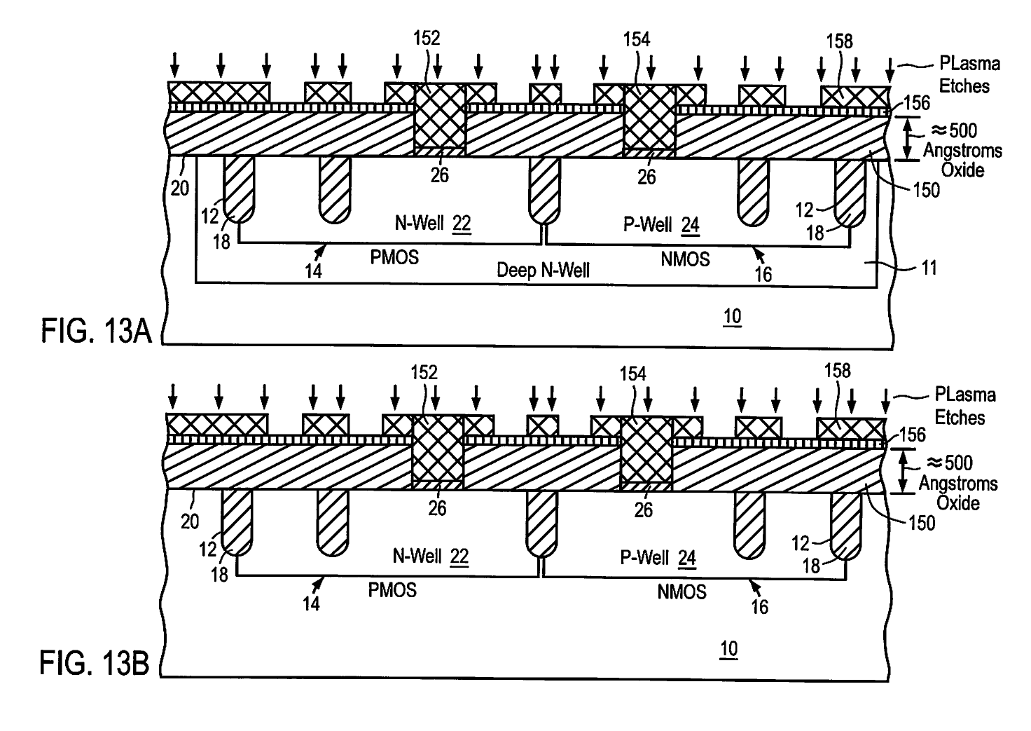

With reference to FIG. 13A and FIG. 13B, photoresist etch barriers 152 and 154 are left in place and a new photoresist layer is deposited (Step 408a), masked (Step 408b), and developed (Step 408c) to form a new photoresist etch barrier 158 that exposes areas of nitride/oxide layer 156/150 where holes are to be etched down to the Silicon substrate for source, drain, and back gate contacts.

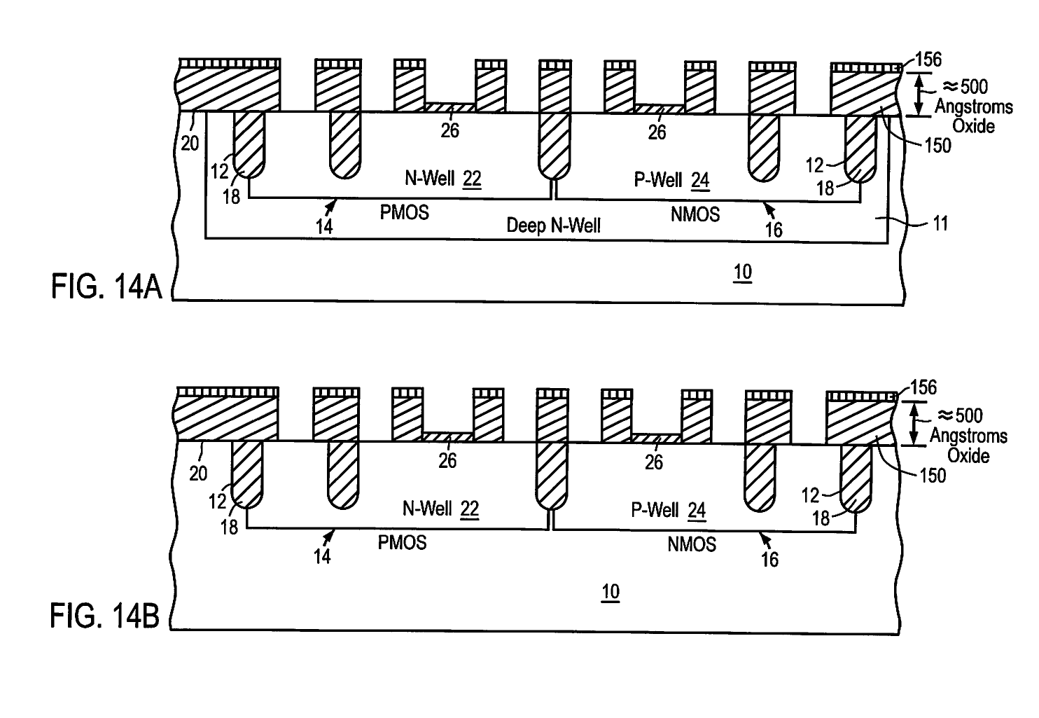

With reference to FIG. 14A and FIG. 14B, surface contact openings are created (Step 409), which may include performing plasma etches to etch away nitiride layer 156 and oxide layer 150 in the exposed areas to create openings for surface contacts for the source, drain and back gate surface contact of each of the NMOS and PMOS devices.

Then, all photoresist is removed (Step 410) to leave contact openings for source, drain, gate and back gate surface contacts.

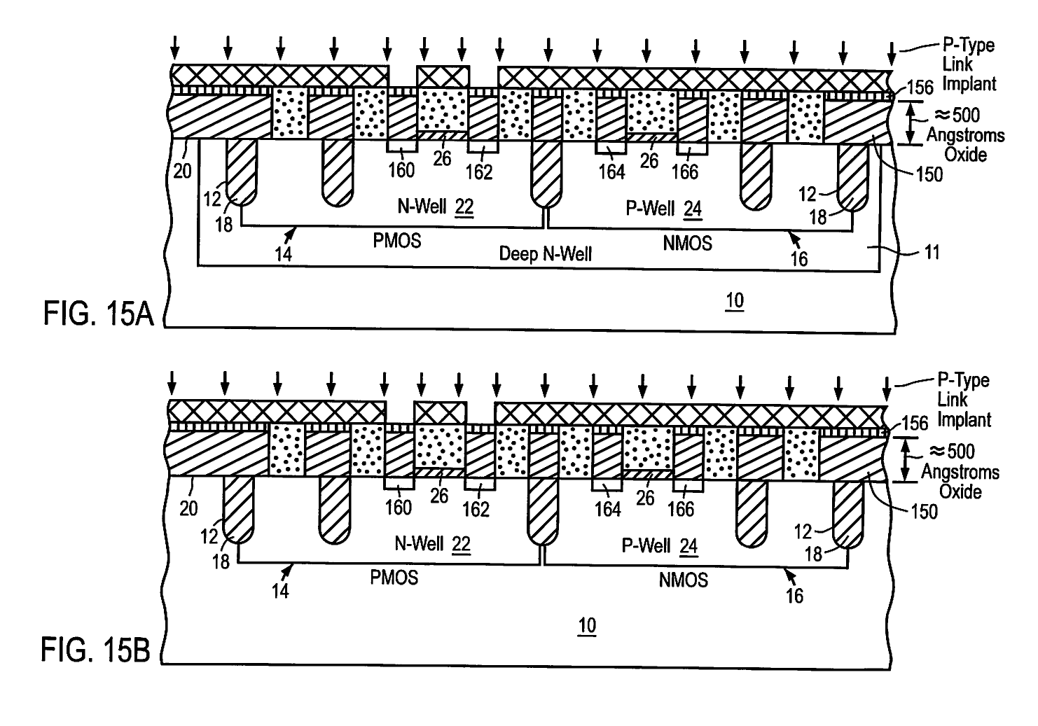

With reference to FIG. 15A and FIG. 15B, a Polycrystalline Silicon layer is deposited (Step 411a), such as by CVD, over the entire wafer and polished back (Step 411b), such as by CMP, to a state where it is flush with the top of layer 156. The Polycrystalline Silicon (polysilicon) layer is preferably undoped Polycrystalline Silicon (undoped polysilicon).

PMOS link regions are then created (Step 412), such as by depositing photoresist (Step 412a), masking (Step 412b), and developing (Step 412c), to create implant barriers everywhere except where P-type link implants are to be formed for the PMOS device. A P-type link implant is performed (Step 412d), such as by ion implantation, to form shallow link regions 160 and 162.

NMOS link regions are created (Step 413), such as by depositing photoresist (Step 413a), masking (Step 413b), and developing (Step 413c), to create implant barriers everywhere except where N-type link implants are to be performed for the NMOS device. An N-type link implant is performed (Step 413d) to form shallow link regions 164 and 166.

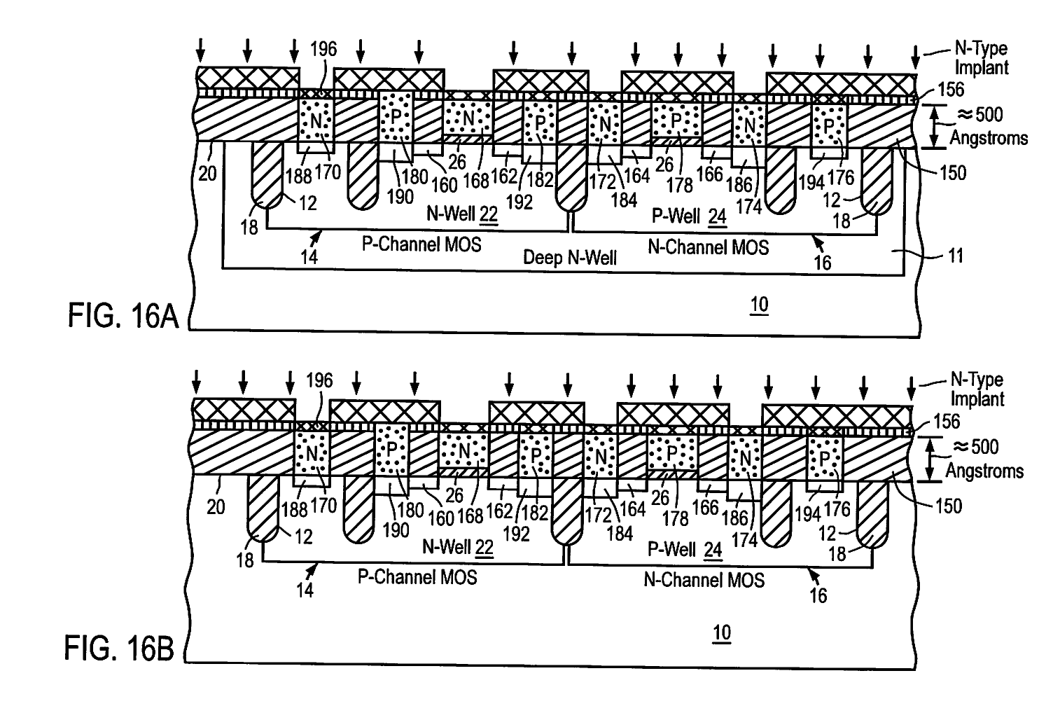

With reference to FIG. 16A and FIG. 16B, certain surface contacts of PMOS and NMOS devices are doped N-type (Step 414), such as for example by: depositing photoresist (Step 414a), masking (Step 414b), and developing (Step 414c), to form implant barriers everywhere but over the PMOS gate (the PMOS gate surface contact can also be doped P type) and back gate surface contacts, 168 and 170, respectively, and everywhere but over the NMOS source and drain surface contacts, 172 and 174, respectively. An N-type ion implantation process is performed to dope the exposed polysilicon surface contacts (Step 414d),

Certain surface contacts of PMOS and NMOS devices are doped P-type (Step 415), such as for example by: depositing photoresist (Step 415a), masking (Step 415), and developing (Step 415) to form implant barriers everywhere but over the NMOS gate (the NMOS gate surface contact can also be doped N type) and back gate surface contacts, 178 and 176, respectively, and everywhere but over the PMOS source and drain surface contacts, 180 and 182, respectively. A P-type ion implantation process is performed to dope the exposed polysilicon surface contacts (Step 415).

With further reference to FIG. 16A and FIG. 16B, self-aligned source and drain regions are formed in each o PMOS and NMOS devices (Step 416), such as by performing a thermal drive-in and anneal process (Step 416a) to activate the implanted impurities and cause impurities to diffuse from the polysilicon surface contacts into the underlying substrate to form self-aligned source and drain regions 184 and 186 and ohmic contact 188 of NMOS device and source and drain regions 180 and 192 and back gate ohmic contact 188 of the PMOS device.

Silicide is then formed on tops of polysilicon surface contacts (Step 417) to lower the surface contacts resistivity.

A dielectric layer is deposited (Step 418a), masked (Step 417b), and contact openings etched (Step 418c), to expose silicide caps of surface contacts to which metal interconnects are to be formed, and metal deposited (Step 418d), and etched (Step 418e), to form desired interconnects.

Poly level interconnects may optionally be formed in this embodiment by etching poly-level interconnect trenches in oxide 150 down to the oxide of the field (Step 419a) and filling these trenches with polysilicon (Step 419b), doping the polysilicon (Step 419c), and forming silicide on the polysilicon (Step 419d).

The process ends here although additional processing steps may be added to this process.

### Exemplary Embodiments of a Metal-Oxide-Semiconductor (MOS) Transistor

It will be apparent in light of the detailed description provided herein above, that a variety of semiconductor devices, including for example transistor devices, may be formed or made using the various processes and methods described. Among these semiconductor devices are included without limitation Metal-Oxide-Semiconductor (MOS) transistors and Complementary Metal-Oxide-Semiconductor (CMOS) transistors.

In accordance with one non-limiting example of such a semiconductor is a Metal-Oxide-Semiconductor (MOS) transistor comprising: an active area defined within a semiconductor substrate for the MOS transistor; a gate surface contact positioned over the active area and formed over a gate insulator layer and comprising Polycrystalline Silicon (polysilicon) doped with conductivity enhancing impurities; source and drain surface contacts comprising Polycrystalline Silicon (polysilicon) doped to a first conductivity type, the source surface contact formed so that it is positioned away from a first side of the gate surface contact and spaced by a first photo-lithographically defined distance away from the gate surface contact; and the drain surface contact formed such that it is positioned away from a second side of the gate surface contact and spaced by a second photo-lithographically defined distance away from the gate surface contact; self-aligned source and drain regions doped to the first conductivity type and formed in the semiconductor substrate so as to be in electrical contact with the source and drain surface contacts, respectively; and an insulator formed between the source and gate surface contacts and between the drain and gate surface contacts.

This MOS transistor may further include silicide formed on a top surface of the source, drain, and gate polysilicon surface contacts, wherein the insulator may include Silicon Dioxide or other insulating material.

The MOS transistor may be or include complementary MOS transitors or devices formed on a common substrate and including for example a P-channel MOS transistor (PMOS transistor) and an N-channel MOS transistor (NMOS transistor).

The MOS transistor may be fabricated according to 45 nanometer design rules, and wherein gate oxide comprises a layer of gate oxide which is 10 to 12 Angstroms thick for 45 nanometer design rules, and wherein the deposited layer of polysilicon from which the polysilicon surface contacts are be formed comprises a layer of polysilicon which is substantially 500 Angstroms (50 nanometers) thick.

The MOS transistor may follow a predetermined N-nanometer horizontal design rule is used to fabricate the CMOS transistor, and wherein the layer of polysilicon from which the polysilicon surface contacts are be formed comprises a layer of polysilicon which has a thickness having a vertical dimension that is substantially the same as the N-nanometer horizontal design rule dimension.

The MOS transistor may have a source, drain, and gate surface contact where a vertical height of the source, drain, and gate surface contacts, and back gate surface if used, being about equal to the channel length of the CMOS transistor, such as to provide a proportional scaling of the vertical height dimension of the surface contacts with the horizontal channel length dimension as the CMOS transistor channel lengths become smaller and smaller; and the vertical heights of the source, drain, and gate surface contacts, and back gate surface if used, being shorter than the height of taller surface contacts formed from layers with larger thicknesses than the thickness. The shorter vertical height surface contacts yield a transistor structure having less over-etch into the underlying transistor active areas so that shallower source and drain regions may be formed and exhibiting lower leakage current for the CMOS transistor, as compared to larger over-etches produced by taller surface contacts that result from a thicker polysilicon layer.

When silicides are present, the silicides on the tops of the polysilicon surface contacts prevent penetrating the source and drain regions and shorting them out as would more likely result when silicides are formed directly on the surface of the substrate.

When formed according to the described processes, the source and drain surface contacts are spaced from the gate surface contact by the minimum distance allowed by the design rules.

The MOS transistor may also further include highly conductive link regions in the substrate doped to the first conductivity type and electrically coupling the source and drain regions with a channel region of the substrate under the gate insulator.

In a further non-limiting example, the MOS transistor may include a layer of Silicon Nitride deposited on the surface of the substrate between at least the gate surface contact and the source and drain surface contacts at least in the active area under suitable process conditions such that the different rates of thermal expansion of the Silicon semiconductor substrate and the Silicon Nitride layer cause stress to be induced in the single crystal Silicon substrate in a channel region of the MOS transistor.

### Additional Exemplary Embodiments of the Process and Structures

It may be appreciated in light of the description provide here, that the various structures and substructures described herein relative to particular exemplary embodiments may be used in different combinations and permutations without departing from the invention. Therefore, although four primary processes 100, 200, 300, 400 and some variants thereof have been described relative to forming both triple-well devices and non-triple-well or double well devices and relative to strained and unstrained substrate have been specifically described, the various process and partial process steps employed to achieve a particular semiconductor structure or substructure may be combined in ways not specifically set forth in this description. In like manner, certain intermediary steps may be performed starting from a different substrate, and additional steps may be inserted or steps substituted without departing from the invention.

Although aspects of the invention has been described in terms of the preferred and alternative embodiments disclosed herein, those skilled in the art will appreciate that other alternative embodiments may also exist. All such alternative embodiments are intended to be within the scope of the claims appended hereto.

What is claimed is:

1. A process for making a complementary Metal-Oxide-Semiconductor (CMOS) transistor comprising:
forming a Shallow Trench Isolation (STI) region in a P doped strained or unstrained Silicon semiconductor substrate to define a first active area for a P-channel MOS transistor (PMOS transistor) and a different second active area for a N-channel MOS transistor (NMOS transistor);
implanting an N-type well in said active area of said PMOS transistor and implanting a P-type well in said active area of said NMOS transistor;
forming a layer of Silicon Dioxide gate insulator over the semiconductor substrate;
masking and etching to remove said gate oxide from at least areas in said active areas of said PMOS and NMOS transistors where source and drain surface contacts are to be formed and, if back gate contacts are to be used, from the area where said back gate contacts are to be formed; and
depositing a layer of Polycrystalline Silicon (polysilicon) over the wafer; and masking and etching said layer of Polycrystalline Silicon to: (i) define at least a source, gate and drain polysilicon surface contact and a back gate polysilicon surface contact within said active area of said PMOS device with said gate surface contact located over said gate oxide, and (ii) define at least a source, gate and drain polysilicon surface contact and a back gate polysilicon surface contact within said active area of said NMOS device with said gate surface contact located over said gate oxide.

2. A process according to claim 1, wherein the STI region is formed by etching STI trenches; filling said STI trenches with an insulator material; and planarizing said insulator material so as to be flush with the top surface of said substrate.

3. A process according to claim 2, wherein the insulator material comprises Silicon Dioxide.

4. A process according to claim 1, further comprising the following steps after depositing said layer of Polycrystalline Silicon (polysilicon) over the wafer and before masking and etching said layer of Polycrystalline Silicon:
forming a first implant mask by depositing and developing a photoresist layer to cover first predetermined areas of said deposited layer of Polycrystalline Silicon;
ion implanting N-type conductivity enhancing impurities into areas of said deposited layer of Polycrystalline Silicon exposed by said first implant mask;
forming a second implant mask by removing said first implant mask and depositing and developing a photoresist layer to cover second predetermined areas of said layer of Polycrystalline Silicon; and
ion implanting P-type conductivity enhancing impurities into areas of said layer of Polycrystalline Silicon exposed by said second implant mask.

5. A process according to claim 1, further comprising depositing a layer of Silicon Nitride on top of said layer of Polycrystalline Silicon prior to said masking and etching said layer of Polycrystalline Silicon.

6. A process according to claim 1, wherein said masking and etching to define polysilicon surface contacts creates gaps between said surface contacts, and the process further comprising:
depositing a layer of Silicon Dioxide to a thickness at least sufficient to fill said gaps between said polysilicon surface contacts; and
planarizing said layer of said Silicon Dioxide so as to leave its top surface approximately flush with the top of said layer of Silicon Nitride on top of said polysilicon.

7. A process according to claim 1, further comprising:
forming a first link implant mask using a photoresist and ion implanting the link regions of said PMOS transistor using N-type conductivity enhancing impurities; and
forming a second link implant mask using a photoresist and ion implanting the link regions of said NMOS transistor using P-type conductivity enhancing impurities.

8. A process according to claim 6, further comprising:
performing a thermal drive-in and anneal process step to cause conductivity enhancing impurities from said polysilicon surface contacts to diffuse into the underlying semiconductor substrate to form source and drain regions for each of said PMOS and NMOS devices and so as to form ohmic contacts for each of said back gate contacts;
removing all photoresist and removing all Silicon Nitride from on top of said polysilicon surface contacts; and
forming silicide on the tops of all said polysilicon surface contacts.

9. A process according to claim 1, further comprising the step of performing ion implantation of N-type conductivity enhancing impurities into each of the active areas for said PMOS and NMOS transistors so as to form a deep N well for each complementary pair of PMOS and NMOS transistors which encompasses the N well of said PMOS transistor and said P well of said NMOS transistor.

10. A process according to claim 1, wherein 45 nanometer design rules are used to fabricate said CMOS transistor, and wherein the step of growing gate oxide comprises growing a layer of gate oxide which is 10 to 12 Angstroms thick for 45 nanometer design rules, and wherein the step of depositing a layer of polysilicon from which the polysilicon surface contacts will be formed comprises depositing a layer of polysilicon which is substantially 500 Angstroms (50 nanometers) thick.

11. A process according to claim 1, wherein a predetermined N-nanometer horizontal design rule is used to fabricate said CMOS transistor, and wherein the step of depositing the layer of polysilicon from which the polysilicon surface contacts will be formed comprises depositing a layer of polysilicon which has a thickness having a vertical dimension that is substantially the same as the N-nanometer horizontal design rule dimension.

12. A process according to claim 1, wherein:
a vertical height of said source, drain, and gate surface contacts, and back gate surface if used, being about equal to the channel length of the CMOS transistor, such as to provide a proportional scaling of the vertical height dimension of the surface contacts with the horizontal channel length dimension as the CMOS transistor channel lengths become smaller and smaller; and
said vertical heights of said source, drain, and gate surface contacts, and back gate surface if used, being shorter than the height of taller surface contacts formed from layers with larger thicknesses than said thickness.

13. A process according to claim 12, wherein the shorter vertical height surface contacts yield a transistor structure having less over-etch into the underlying transistor active areas so that shallower source and drain regions may be formed and exhibiting lower leakage current for the CMOS transistor, as compared to larger over-etches produced by taller surface contacts that result from a thicker polysilicon layer.

14. A process according to claim 10, wherein forming silicides on the tops of the polysilicon surface contacts prevents penetrating the source and drain regions and shorting them out as would more likely result when silicides are formed directly on the surface of the substrate.

15. A process for making complementary Metal-Oxide-Semiconductor (CMOS) devices using a Silicon Nitride layer to achieve a strained Silicon substrate, comprising:
depositing a layer of Polycrystalline Silicon (polysilicon) over at least areas of a Silicon semiconductor substrate where the CMOS device is to be formed;
depositing a first layer of Silicon Nitride on top of said Polycrystalline Silicon (polysilicon);
masking and etching said layer of polysilicon to define at least source, gate, and drain surface contacts, and a back gate surface contact if used within said active area with said gate surface contact located over said gate oxide and said masking and etching creating gaps between said surface contacts;
depositing an effective thickness of a second layer of Silicon Nitride over the entire wafer so as to be in contact with said Silicon substrate between at least said gate and said source and drain surface contacts under process conditions which will cause differential thermal expansion rates between said Silicon semiconductor substrate and said second layer of Silicon Nitride to place said Silicon semiconductor substrate under strain;
depositing a layer of Silicon Dioxide to a thickness at least sufficient to fill said gaps between said surface contacts not filled by said second Silicon Nitride layer; and
planarizing said layer of Silicon Dioxide so as to leave its top surface substantially flush with the top of said deposited second layer of Silicon Nitride.

16. A process according to claim 15, wherein the depositing a layer of Polycrystalline Silicon (polysilicon) over at least areas of a semiconductor substrate where the CMOS device is to be formed comprises depositing a layer of Polycrystalline Silicon (polysilicon) that substantially the same thickness in vertical dimension or height as the horizontal feature size dimension of the channel length of the CMOS devices.

17. A process according to claim 15, wherein the etching of the Polycrystalline Silicon layer is line, gap, line, gap, line for the source, gate, and drain surface electrodes, control over the gap distance between surface electrodes is controlled photo-lithographically so that the horizontal space between the gate and each of the source and drain surface contacts can be the minimum distance permitted by the design rules.

18. A process according to claim 15, further comprising:
performing a link region implant ion implantation in the regions between said gate surface electrode and said source and drain surface electrodes to form highly conductive link areas in said substrate.

19. A process according to claim 15, further comprising:
removing said layer of Silicon Nitride on the tops of said polysilicon surface contacts;
masking and doping said polysilicon surface contacts with predetermined conductivity enhancing impurities;
performing a thermal drive-in and anneal step to cause conductivity enhancing impurities from said polysilicon surface contacts to diffuse into the underlying semiconductor substrate to form source and drain regions; and
forming silicide on top of said polysilicon surface contacts.

20. A process according to claim 15, wherein 45 nanometer design rules are used to fabricate said CMOS transistor, and wherein the step of growing gate oxide comprises growing a layer of gate oxide which is 10 to 12 Angstroms thick for 45 nanometer design rules, and wherein the step of depositing a layer of polysilicon from which the polysilicon surface contacts will be formed comprises depositing a layer of polysilicon which is substantially 500 Angstroms (50 nanometers) thick.

21. A process according to claim 15, wherein a predetermined N-nanometer horizontal design rule is used to fabricate said CMOS transistor, and wherein the step of depositing the layer of polysilicon from which the polysilicon surface contacts will be formed comprises depositing a layer of polysilicon which has a thickness having a vertical dimension that is substantially the same as the N-nanometer horizontal design rule dimension.

22. A process according to claim 15, wherein:
a vertical height of said source, drain, and gate surface contacts, and back gate surface if used, being about equal to the channel length of the CMOS transistor, such as to provide a proportional scaling of the vertical height dimension of the surface contacts with the horizontal channel length dimension as the CMOS transistor channel lengths become smaller and smaller; and
said vertical heights of said source, drain, and gate surface contacts, and back gate surface if used, being shorter than the height of taller surface contacts formed from layers with larger thicknesses than said thickness.

23. A process according to claim 22, wherein the shorter vertical height surface contacts yield a transistor structure having less over-etch into the underlying transistor active areas so that shallower source and drain regions may be formed and exhibiting lower leakage current for the CMOS transistor, as compared to larger over-etches produced by taller surface contacts that result from a thicker polysilicon layer.

24. A process according to claim 19, wherein forming silicides on the tops of the polysilicon surface contacts prevents penetrating the source and drain regions and shorting them out as would more likely result when silicides are formed directly on the surface of the substrate.

25. A process according to claim 15, further comprising prior to depositing said layer of Polycrystalline Silicon (polysilicon) over at least areas of a semiconductor substrate where the CMOS device is to be formed, the following steps:
etching Shallow Trench Isolation (STI) trenches in a unstrained Silicon semiconductor substrate doped to a first conductivity type to define an active area for an MOS transistor;
filling said STI trenches with Silicon Dioxide;
planarizing said Silicon Dioxide so as to be flush with the top surface of said substrate;
implanting a well of a second conductivity type in said active area of said MOS transistor;
performing a threshold adjustment ion implantation in said well of said second conductivity type for said MOS transistor;
thermally growing a layer of Silicon Dioxide gate insulator (gate oxide) over the entire surface of said wafer; and
masking and etching to remove said gate oxide from at least areas in said active area where source and drain surface contacts are to be formed and, if a back gate contact is to be used, from the area where said back gate contact is to be formed.

26. A Metal-Oxide-Semiconductor (MOS) transistor comprising:
an active area defined within a semiconductor substrate for said MOS transistor;
a gate surface contact positioned over said active area and formed over a gate insulator layer and comprising Polycrystalline Silicon (polysilicon) doped with conductivity enhancing impurities;
source and drain surface contacts comprising Polycrystalline Silicon (polysilicon) doped to a first conductivity type,
said source surface contact formed so that it is positioned away from a first side of said gate surface contact and spaced by a first photo-lithographically defined distance away from said gate surface contact; and
said drain surface contact formed such that it is positioned away from a second side of said gate surface contact and spaced by a second photo-lithographically defined distance away from said gate surface contact;
self-aligned source and drain regions doped to said first conductivity type and formed in said semiconductor substrate so as to be in electrical contact with said source and drain surface contacts, respectively; and
an insulator formed between said source and gate surface contacts and between said drain and gate surface contacts.

27. The MOS transistor of claim 26, further comprising silicide formed on a top surface of said source, drain, and gate polysilicon surface contacts.

28. The MOS transistor of claim 27, wherein said insulator comprises Silicon Dioxide.

29. The MOS transistor of claim 27, further comprising complementary MOS devices formed on a common substrate and including a P-channel MOS transistor (PMOS transistor) and an N-channel MOS transistor (NMOS transistor).

30. The MOS transistor of claim 27, wherein said MOS transistor is fabricated according to 45 nanometer design rules, and wherein gate oxide comprises a layer of gate oxide which is 10 to 12 Angstroms thick for 45 nanometer design rules, and wherein the deposited layer of polysilicon from which the polysilicon surface contacts are be formed comprises a layer of polysilicon which is substantially 500 Angstroms (50 nanometers) thick.

31. The MOS transistor of claim 27, wherein a predetermined N-nanometer horizontal design rule is used to fabricate said CMOS transistor, and wherein the layer of polysilicon from which the polysilicon surface contacts are be formed comprises a layer of polysilicon which has a thickness having a vertical dimension that is substantially the same as the N-nanometer horizontal design rule dimension.

32. The MOS transistor of claim 27, wherein:
a vertical height of said source, drain, and gate surface contacts, and back gate surface if used, being about equal to the channel length of the CMOS transistor, such as to provide a proportional scaling of the vertical height dimension of the surface contacts with the horizontal channel length dimension as the CMOS transistor channel lengths become smaller and smaller; and
said vertical heights of said source, drain, and gate surface contacts, and back gate surface if used, being shorter than the height of taller surface contacts formed from layers with larger thicknesses than said thickness.

33. The MOS transistor of claim 32, wherein the shorter vertical height surface contacts yield a transistor structure having less over-etch into the underlying transistor active areas so that shallower source and drain regions may be formed and exhibiting lower leakage current for the CMOS transistor, as compared to larger over-etches produced by taller surface contacts that result from a thicker polysilicon layer.

34. The MOS transistor of claim 27, wherein the silicides on the tops of the polysilicon surface contacts prevents penetrating the source and drain regions and shorting them out as would more likely result when silicides are formed directly on the surface of the substrate.

35. The MOS transistor of claim 27, wherein said source and drain surface contacts are spaced from said gate surface contact by the minimum distance allowed by the design rules.

36. The MOS transistor in claim 27, further comprising:
a layer of Silicon Nitride deposited on the surface of said substrate between at least said gate surface contact and said source and drain surface contacts at least in said active area under suitable process conditions such that the different rates of thermal expansion of said Silicon semiconductor substrate and said Silicon Nitride layer cause stress to be induced in said single crystal Silicon substrate in a channel region of said MOS transistor.

37. The MOS transistor in claim 27, further comprising:
highly conductive link regions in said substrate doped to said first conductivity type and electrically coupling said source and drain regions with a channel region of said substrate under said gate insulator.
